(19) United States
(12) Patent Application Publication
(10) Pub. No.: US 2018/0246581 A1
(43) Pub. Date: Aug. 30, 2018

(54) ORGANIC ELECTROLUMINESCENCE MODULE, SMART DEVICE, AND ILLUMINATING DEVICE

(71) Applicant: Konica Minolta, Inc., Tokyo (JP)

(72) Inventors: Kazuyoshi OMATA, Koufu-shi, Yamanashi (JP); Natsuki YAMAMOTO, Kawasaki-shi, Kanagawa (JP); Tsukasa YAGI, Higashinada-ku, Kobe-shi, Hyogo (JP)

(21) Appl. No.: 15/753,852

(22) PCT Filed: Mar. 15, 2016
(86) PCT No.: PCT/JP2016/058071

§ 371 Date: Feb. 20, 2018

(30) Foreign Application Priority Data
Sep. 17, 2015 (JP) 2015-183615

(51) Int. Cl. G06F 3/02; G06F 3/044; G09F 9/30; G09G 3/30; H01L 27/32; H01L 51/50; H05B 33/08; H05B 33/28

(52) U.S. Cl. CPC G06F 3/0202; G06F 3/044; G09F 9/30; H05B 33/28; H01L 27/32; H01L 51/50; H05B 33/08; G09G 3/30

(57) ABSTRACT

An object of the present invention is to provide an organic EL module which includes an organic EL element of an electrode configuration, having both of a light emitting function and a hovering detection function, has a specific control circuit configuration, is capable of being small formatted and miniaturized, and is capable of simplifying a process, and a smart device and an illuminating device including the organic EL module.

An organic EL module of the present invention includes: an electrostatic capacitance type hovering detection circuit unit having a hovering detection function; and a light emitting element driving circuit unit driving an organic EL panel, in which the organic EL panel includes a pair of planar electrodes in internal facing positions, the pair of electrodes is connected to the light emitting element driving circuit unit, any one of the pair of electrodes is a hovering detection electrode, and the hovering detection electrode is connected to the hovering detection circuit unit.

### TECHNICAL FIELD

The present invention relates to an organic electroluminescence module having a hovering detection function, and a smart device and an illuminating device including the organic electroluminescence module.

### BACKGROUND ART

In the related art, examples of a planar light source body include a light emitting diode using a light guide plate (hereinafter, simply referred to as an “LED”), an organic light emitting diode (hereinafter, referred to as an organic electroluminescence element or simply referred to as an “OLED”), or the like.

Since around 2008, a yield of a smart device (for example, a smart phone, a tablet, and the like) has dramatically increased in worldwide. In such a smart device, a key including a flat surface is used from the viewpoint of operation properties of the smart device. For example, an icon portion, which is a common function key button disposed in a lower region of the smart device, corresponds to the key. There is a case where, for example, three types of marks representing “home” (displayed as a mark such as a quadrangle), “return” (displayed as an arrow mark or the like), and “searching” (displayed as a magnifying glass mark) are provided in the common function key button.

A method is disclosed in which in a case where, for example, an LED or the like is used according to a pattern shape of a mark to be displayed, such a common function key button is used by disposing a planar emitting device such as an LED light guide plate in the smart device in advance, from the viewpoint of improving visibility (for example, refer to Patent Literature 1).

In addition, a method is disclosed in which as an electrostatic capacitance type information input unit using an LED light source, sensitivity of a sensor electrode increases, and thus, a change in electrostatic capacitance is reliably detected by a sensor circuit, and in order to stably process an input operation of a user, an adhesive agent layer having higher electric permittivity than that of an air layer having the same shape is disposed in a position avoiding a portion of an icon or the like, between a flexible print circuit in which the sensor electrode is formed (hereinafter, simply referred to as an “FPC”) and a front panel, and thus, the accuracy of the detection electrode detecting the electrostatic capacitance is improved (for example, refer to Patent Literature 2).

Recently, in a display method of the icon portion, there is a move of using a surface-emitting type organic electroluminescence device in the method using an LED light source described above, in order to obtain lower power consumption and to improve homogeneousness of a light emission brightness. In such an organic electroluminescence device, a mark or the like with respect to cover glass side, configuring the icon portion, is printed in advance, and the portion is disposed on a rear side, and thus, a display function can be expressed.

On the other hand, when the smart device is used, a touch detection function is essential, and it is general that an electrostatic capacitance type hovering detection device for touch detection is disposed at a lower side of the cover glass until reaching a display unit and a common function key portion.

There are many cases of using a touch detection device in which a film/a film type touch sensor is laminated by being enlarged to the same size as that of the cover glass. In particular, in the case of a model in which there is no restriction on a thickness, there is the case of using a glass/glass type touch detection device. Recently, there are many cases of adopting an electrostatic capacitance type touch detection system. For main display, a system including a fine electrode pattern in each of an x axis and a y axis direction, which is referred to as a “projection electrostatic capacitance system”, is adopted. In this system, touch detection of two or more points, which is referred to as so-called “multitouch”, can be performed.

Such a touch sensor is used, and thus, a light emitting device not having a touch function has been used in a portion of a common function key. However, recently, a so-called “in-cell” type or “on-cell” type display appears, and thus, it has been strongly required to uniquely provide a touch detection function in a light emitting device for a common function key.

On the other hand, recently, a system of performing detection in a state of being approached with a finger on a touch panel, that is, a method of performing hovering detection on the touch panel (also referred to as proximity detection) has been actively considered (for example, refer to Patent Literature 3 and Patent Literature 4).

In particular, in the case of the surface-emitting type organic electroluminescence device, a positive electrode, a negative electrode, or a metal foil layer used for protection, which configure the organic electroluminescence element, negatively affect the detection of a change in the surface type electrostatic capacitance type electrostatic capacitance, and thus, in the case of applying an electrostatic touch function or an electrostatic hovering function to the organic electroluminescence device, as illustrated in FIG. 1 described below, it is necessary to dispose an electric connection unit including an electrostatic capacitance type detection circuit and a wiring portion on a flexible substrate, for example, a touch detection electrode for touch function detection configured of a flexible print circuit (simply referred to as an FPC) or a hovering detection electrode for hovering function detection on the light emitting surface side, as an assembly, in a separate configuration, along with an organic electroluminescence panel, and there is a large restriction in the configuration. In a method of disposing such an assembly, it is necessary to additionally obtain a device for touch function detection or a device for hovering function detection (for example, an FPC), and there are problems such as an economic load, thickening of a device, and an increase in man-hour of a manufacturing process.

Accordingly, development of an organic electroluminescence module is required in which an organic electroluminescence element, and a wiring material controlling the driving of the organic electroluminescence element are efficiently arranged, downsizing and miniaturization are attained, and adequacy with respect to a smart device having a hovering detection function is provided.

### CITATION LIST

### Patent Literature

Patent Literature 1: JP 2012-194291 A

Patent Literature 2: JP 2013-065429 A

Patent Literature 3: JP 2014-099189 A

Patent Literature 4: JP 2014-229302 A

### SUMMARY OF INVENTION

### Technical Problem

The present invention has been made in consideration of the problems and circumstances described above, and an object of the present invention is to provide an organic electroluminescence module of a hovering detection system which includes an organic electroluminescence element including an electrode, having both of a light emitting function and a hovering detection function, and a specific control circuit, is capable of being small formatted and miniaturized, and is capable of simplifying a manufacturing process, and a smart device and an illuminating device including the organic electroluminescence module.

### Solution to Problem

As a result of intensive study of the present inventors for attaining the object described above, it has been found that the object described above can be attained by an organic electroluminescence module having a configuration in which any one electrode of an organic electroluminescence panel is set to function as a hovering detection electrode, and a hovering detection circuit unit and a light emitting element driving circuit unit are connected to the organic electroluminescence panel, and thus, the present invention has been made.

That is, the object of the present invention can be attained by the following means.

1. An organic electroluminescence module having a hovering detection function, the module including:

a hovering detection circuit unit including an electrostatic capacitance type hovering detection circuit portion; and

a light emitting element driving circuit unit including a light emitting element driving circuit portion which drives an organic electroluminescence panel,

wherein the organic electroluminescence panel includes a pair of planar electrodes in facing internal positions,

the pair of electrodes is connected to the light emitting element driving circuit unit, and

any one of the pair of electrodes is a hovering detection electrode, and the hovering detection electrode is connected to the hovering detection circuit unit.

2. The organic electroluminescence module according to Item. 1,

wherein the hovering detection circuit unit and the light emitting element driving circuit unit are connected to one common ground.

3. The organic electroluminescence module according to Item. 1,

wherein the hovering detection circuit unit and the light emitting element driving circuit unit are each independently connected to a ground.

4. The organic electroluminescence module according to any one of Items. 1 to 3,

wherein a light emitting period of the organic electroluminescence panel which is controlled by the light emitting element driving circuit portion and a hovering sensing period which is controlled by the hovering detection circuit portion are in a state of being separated from each other.

5. The organic electroluminescence module according to Item. 4,

wherein electric capacitance of the organic electroluminescence panel is in a state of not being detected during the hovering sensing period.

6. The organic electroluminescence module according to any one of Items. 1 to 5,

wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential such that the electric capacitance of the organic electroluminescence panel is not detected during the hovering sensing period.

7. The organic electroluminescence module according to any one of Items. 1 to 5,

wherein the light emitting period of the organic electroluminescence panel which is controlled by the light emitting element driving circuit portion and the hovering sensing period which is controlled by the hovering detection circuit portion are separated from each other, and the pair of electrodes is in a state of the same potential such that the electric capacitance of the organic electroluminescence panel is not detected during the hovering sensing period.

8. The organic electroluminescence module according to any one of Items. 1 to 5,

wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential, and the pair of electrodes is in a state of the same potential, such that the electric capacitance of the organic electroluminescence panel is not detected during the hovering sensing period.

9. The organic electroluminescence module according to any one of Items. 1 to 5,

wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential, and the pair of electrodes is in a state of being short-circuited, such that the electric capacitance of the organic electroluminescence panel is not detected during the hovering sensing period.

10. The organic electroluminescence module according to any one of Items. 1 to 5,

wherein the organic electroluminescence module is in a driving system in which the organic electroluminescence panel which is controlled by the light emitting element driving circuit portion continuously emits light, and the hovering sensing period which is controlled by the hovering detection circuit portion periodically appears.

11. The organic electroluminescence module according to any one of Items. 1 to 10,

wherein a reverse applied voltage period is provided at the end of the light emitting period.

12. The organic electroluminescence module according to any one of Items. 1 to 11, further including:

a capacitor between wirings connecting the grounds of the light emitting element driving circuit portion and the hovering detection circuit portion together.

13. A smart device, including:

the organic electroluminescence module according to any one of Items. 1 to 12.

14. An illuminating device, including:

the organic electroluminescence module according to any one of Items. 1 to 12.

### Advantageous Effects of Invention

According to the means of the present invention described above, it is possible to provide an organic electroluminescence module which includes an organic electroluminescence element of an electrode configuration, having both of a light emitting function and a hovering detection function, has a specific control circuit configuration, is capable of being small formatted and miniaturized, and is capable of simplifying a process, and a smart device and an illuminating device including the organic electroluminescence module.

The technical characteristics of the organic electroluminescence module having the configuration defined in the present invention, and the expression mechanism of the effect thereof are as follows.

In the related art, an organic electroluminescence module applied to an icon display unit of smart media, as described in FIG. 1 described below, is configured as an assembly in which a light emitting function and a hovering detection function are separated from each other, by an organic electroluminescence panel including a pair of electrodes units in facing positions, and a hovering detection electrode for hovering detection, for example, a flexible print circuit (FPC), and thus, a thick configuration is obtained, and it is difficult to be small formatted.

For such problems described above, as a representative configuration illustrated in FIG. 2 described below, the organic electroluminescence module of the present invention (hereinafter, simply referred to as an “organic EL module”) has a configuration including a light emitting element driving circuit unit which includes a light emitting element driving circuit portion for controlling light emission of the organic electroluminescence element (hereinafter, simply referred to as an “organic EL element”) between a pair of electrodes disposed in facing positions, as a first electric control member, and a hovering detection circuit unit which allows at least one electrode of the pair of electrodes to function as a hovering detection electrode, and includes a hovering detection circuit portion therein, as a second electric control member, with respect to the organic electroluminescence panel (hereinafter, simply referred to as an “organic EL panel”).

In general, in the configuration of the organic EL panel or the organic EL element, as described above, in the case of applying an anode electrode (a positive electrode) or a cathode electrode (a negative electrode) as the hovering detection electrode (hereinafter, simply referred to as a “detection electrode”), and in a case where electrostatic capacitance between a hovering finger and the hovering detection electrode is set to Cf, and electrostatic capacitance between the anode electrode and the cathode electrode is set to Cel, electrostatic capacitance at the time of hovering is “Cf+Cel”, and is “Cel” in a state of not being approached with the finger, but in a normal case, Cf<Cel is obtained, and thus, it is difficult to perform hovering detection.

In the organic EL module of the present invention, the light emitting element driving circuit unit including the light emitting element driving circuit portion and the hovering detection circuit unit including the hovering detection circuit portion are independently disposed, and when the hovering detection is performed, a switch between the anode electrode (the positive electrode) and the cathode electrode (the negative electrode), and the light emitting element driving circuit portion is turned off, and at least one electrode of the anode electrode (the positive electrode) and the cathode electrode (the negative electrode) is set to be in a state of a floating potential such that the electrostatic capacitance Cel between the anode electrode and the cathode electrode is not detected, and thus, it is possible to perform the hovering detection, and as a result thereof, it is possible to be small formatted and miniaturized, and to simplify a manufacturing process.

Furthermore, a state of a floating potential in the present invention represents a floating potential state of not being connected to a ground of a power source or a device, and the anode electrode (the positive electrode) or the cathode electrode (the negative electrode) at the time of performing the hovering detection obtains a floating potential, and thus, the electrostatic capacitance Cel of the organic EL panel is in a state of not being detected, and as a result thereof, it is possible to perform the hovering detection according to the approach of the finger.

### BRIEF DESCRIPTION OF DRAWINGS

FIG. 1 is a schematic sectional view illustrating an example of a configuration of an organic electroluminescence module of a comparative example.

FIG. 2 is a schematic sectional view of a first embodiment which has a configuration of an organic electroluminescence module of the present invention (an anode electrode is a detection electrode), and includes one common ground.

FIG. 3 is a schematic sectional view of a second embodiment which has the configuration of the organic electroluminescence module of the present invention (the anode electrode is the detection electrode), and includes two grounds.

FIG. 4 is a driving circuit diagram illustrating an example of a circuit driving of the organic electroluminescence module of the first embodiment.

FIG. 5 is a schematic circuit diagram illustrating an example of a configuration of a light emitting element driving circuit unit according to the present invention.

FIG. 6 is a driving circuit diagram illustrating an example of a circuit driving of the organic electroluminescence module of the second embodiment.

FIG. 7 is a timing chart illustrating an example of a light emitting period and a sensing period in a driving circuit (first embodiment) illustrated in FIG. 4.

FIG. 8 is a timing chart illustrating another example (applying a reverse applied voltage) of the light emitting period and the sensing period in the driving circuit (first embodiment) illustrated in FIG. 4.

FIG. 9 is a circuit operating chart illustrating an example of a circuit operation during the light emitting period of the first embodiment.

FIG. 10 is a circuit operating chart illustrating an example of the circuit operation during the sensing period of the first embodiment.

FIG. 11 is a circuit operating chart illustrating an example of a circuit operation during a sensing period of the second embodiment (two grounds).

FIG. 12 is a driving circuit diagram of a third embodiment, which is another example (one ground) of the organic electroluminescence module.

FIG. 13 is a timing chart illustrating an example of a light emitting period and a sensing period in the third embodiment.

FIG. 14 is a circuit operating chart illustrating an example of a circuit operation during the sensing period of the third embodiment.

FIG. 15A is a schematic view for illustrating an electrostatic capacitance difference in a case where there is no finger touch of the sensing period (there is no hovering detection) of the third embodiment.

FIG. 15B is a schematic view for illustrating an electrostatic capacitance difference in a case where there is the finger touch of the sensing period (there is the hovering detection) of the third embodiment

FIG. 16 is a circuit operating chart illustrating an example of a circuit operation during a sensing period of a fourth embodiment, which is another example (one ground) of the organic electroluminescence module.

FIG. 17 is a circuit operating chart illustrating an example of a circuit operation during a sensing period of a fifth embodiment, which is another example (two grounds) of the organic electroluminescence module.

FIG. 18 is a circuit operating chart illustrating an example of a circuit operation during a sensing period of a sixth embodiment, which is another example (one ground, constant light emission) of the organic electroluminescence module.

FIG. 19 is a timing chart which is configured of a light emitting period and an intermittent sensing period during which light is continuously emitted in the sixth embodiment.

FIG. 20 is a schematic sectional view illustrating an example of another configuration (a cathode electrode is a hovering detection electrode) of the organic electroluminescence module of the present invention.

FIG. 21 is a driving circuit diagram of a seventh embodiment which is another example (one ground) of the organic electroluminescence module, in which the cathode electrode is the hovering detection electrode.

FIG. 22 is a driving circuit diagram of an eighth embodiment which is another example (two grounds) of the organic electroluminescence module, in which the cathode electrode is the hovering detection electrode.

FIG. 23 is a schematic configuration diagram illustrating an example of a smart device including the organic electroluminescence module of the present invention.

### DESCRIPTION OF EMBODIMENTS

An organic electroluminescence module of the present invention, having a hovering detection function, includes: a hovering detection circuit unit including an electrostatic capacitance type hovering detection circuit portion; and a light emitting element driving circuit unit including a light emitting element driving circuit portion driving an organic EL panel, in which the organic EL panel includes a pair of planar electrodes in facing internal positions, the pair of electrodes is connected to the light emitting element driving circuit unit, any one of the pair of electrodes is a hovering detection electrode, and the hovering detection electrode is connected to the hovering detection circuit unit. Such characteristics are technical characteristics, common or corresponding to each of claims.

In an embodiment of the present invention, from the viewpoint of being capable of further expressing the objective effects of the present invention, a configuration in which the hovering detection circuit unit and the light emitting element driving circuit unit are connected to one common ground, is a preferred aspect from the viewpoint of being capable of designing a control circuit which is further simplified and has an efficiency.

In addition, in another aspect, a configuration in which the hovering detection circuit unit and the light emitting element driving circuit unit are each independently connected to a ground, is a preferred aspect from the viewpoint of being capable of being small formatted and miniaturized, and of simplifying a process.

In addition, in another aspect, a configuration in which a light emitting period of the organic electroluminescence panel which is controlled by the light emitting element driving circuit portion and a hovering sensing period which is controlled by the hovering detection circuit portion are in a state of being separated from each other, is a preferred aspect from the viewpoint of being capable of obtaining a high detection accuracy.

In addition, a configuration in which electric capacitance of the organic electroluminescence panel is in a state of not being detected during the hovering sensing period, is a preferred aspect from the viewpoint of being capable of obtaining a higher detection accuracy.

In addition, it is preferable that the light emitting period of the organic electroluminescence panel which is controlled by the light emitting element driving circuit unit and the hovering sensing period which is controlled by the hovering detection circuit unit are separated from each other, and at least one electrode of the pair of electrodes is in a state of a floating potential such that the electric capacitance of the organic electroluminescence panel is not detected during the hovering sensing period, from the viewpoint of being capable of more obviously separating the light emitting period and the sensing period from each other.

In addition, it is preferable that the light emitting period of the organic electroluminescence panel which is controlled by the light emitting element driving circuit portion and the hovering sensing period which is controlled by the hovering detection circuit portion are separated from each other, and the pair of electrodes are in a state of the same potential such that the electric capacitance of the organic electroluminescence panel is not detected during the hovering sensing period, from the viewpoint of being capable of more obviously separating the light emitting period and the sensing period from each other.

In addition, it is preferable that the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential state, and the pair of electrodes are in a state of the same potential, such that the electric capacitance of the organic electroluminescence panel is not detected during the hovering sensing period, from the viewpoint of being capable of more obviously separating the light emitting period and the sensing period from each other.

In addition, it is preferable that the light emitting period of the organic electroluminescence panel which is controlled by the light emitting element driving circuit unit and the hovering sensing period which is controlled by the hovering detection circuit unit are separated from each other, and at least one electrode of the pair of electrodes is in a state of a floating potential and in a state of being short-circuited, such that the electric capacitance of the organic electroluminescence panel is not detected during the hovering sensing period, from the viewpoint of being capable of more obviously separating the light emitting period and the sensing period from each other.

In addition, a driving system in which the organic electroluminescence panel which is controlled by the light emitting element driving circuit portion continuously emits light, and the hovering sensing period which is controlled by the hovering detection circuit portion discontinuously (intermittently) appears, is preferable from the viewpoint of being capable of simplifying a circuit and of realizing an efficient sensing function.

In addition, it is preferable that a reverse applied voltage applying period is provided at the end of the light emitting period, from the viewpoint of being capable of more obviously separating the light emitting period and the sensing period from each other.

In addition, a configuration in which a capacitor is provided between wirings connecting the grounds of the light emitting element driving circuit portion and the hovering detection circuit portion together, is preferable from the viewpoint of being capable of allowing the hovering sensing period controlled by the hovering detection circuit portion to discontinuously appear while allowing the light emitting element to continuously emit light.

In the present invention, the organic EL element is an element configured of a pair of facing electrodes and an organic functional layer unit. The organic EL panel indicates a configuration in which the organic EL element is sealed with a sealing resin and a sealing member. The organic EL module has a configuration in which the electrostatic capacitance type hovering detection circuit unit and the light emitting element driving circuit unit are connected to the to the organic EL panel through the electric connect member, and both of the light emitting function and the hovering detection function are provided.

Hereinafter, constituents of the present invention and embodiments and aspects of the present invention will be described in detail with reference to the drawings. Furthermore, herein, “to” representing a numerical range is used as the meaning including numerical values described before and after that as a lower limit value and an upper limit value. Furthermore, in the description of each of the drawings, numerical numbers described in parentheses at the end of the constituent represent reference numerals in each of the drawings.

<<Organic EL Module>>

An organic EL module of the present invention is an organic EL module in which an electric connect member is joined to an organic EL panel, the electric connect member includes a hovering detection circuit unit including an electrostatic capacitance type hovering detection circuit portion, and a light emitting element driving circuit unit including a light emitting element driving circuit portion driving the organic electroluminescence panel, the organic electroluminescence panel includes a pair of planar electrodes in facing internal positions, the pair of electrodes is connected to the light emitting element driving circuit unit, any one of the pair of electrodes is a hovering detection electrode, and the hovering detection electrode is connected to the hovering detection circuit unit.

[Overall Configuration of Organic EL Module]

Before describing the overall configuration of the organic EL module of the present invention, a schematic configuration of an organic EL module of the related art, which is a comparative example, will be described.

[Schematic Configuration of Organic Electroluminescence Module of Related Art]

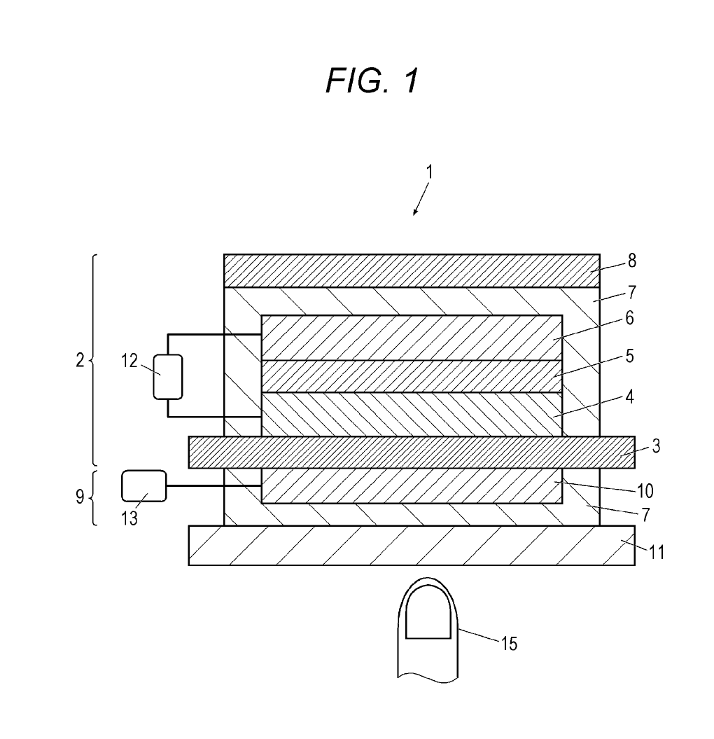

FIG. 1 is a schematic sectional view illustrating an example of a configuration of an organic electroluminescence module of the related art having a touch detection function, which is a comparative example.

In an organic EL module (1) illustrated in FIG. 1, an anode electrode (4, a positive electrode), and an organic functional layer unit (5), for example, configured of a hole injecting layer, a hole transporting layer, a light emitting layer, an electron transporting layer, an electron injecting layer, and the like are laminated on a transparent base material (3), and thus, a light emitting region is configured. A cathode electrode (6, a negative electrode) is laminated on an upper portion of the organic functional layer unit (5), and thus, an organic EL element is configured. An outer circumferential portion of the organic EL element is sealed with an adhesive agent (7) for sealing, and a sealing member (8) is disposed on a front surface thereof in order to prevent noxious gas (oxygen, moisture, and the like) from the external environment from penetrating into the light emitting unit, and thus, an organic EL panel (2) is configured.

In the configuration illustrated in FIG. 1, a light emitting element driving circuit unit (12) controlling light emission is connected between the anode electrode (4) and the cathode electrode (6), which are a pair of electrodes. In addition, in a state of being separated from the organic EL panel (2), for example, a touch detection electrode (10) for touch detection, configured of an electric connection unit (a flexible print circuit) in which an electrostatic capacitance type detection circuit and a wiring portion are disposed on a flexible substrate, is disposed on a surface on a side opposite to a surface on which the organic EL element of the transparent base material (3) is formed, the periphery thereof is sealed with an adhesive agent (7) for sealing, and thus, a touch function detection unit (9) is formed, and cover glass (11) is disposed on an upper surface portion thereof. A touch detection circuit unit (13) for detecting touch of a finger (15) or the like is disposed on the touch function detection electrode (10).

### Schematic Configuration of Organic Electroluminescence Module of Present Invention: First Embodiment

Next, a basic configuration (one ground, first embodiment) of an organic EL module of the present invention having a hovering detection function will be described.

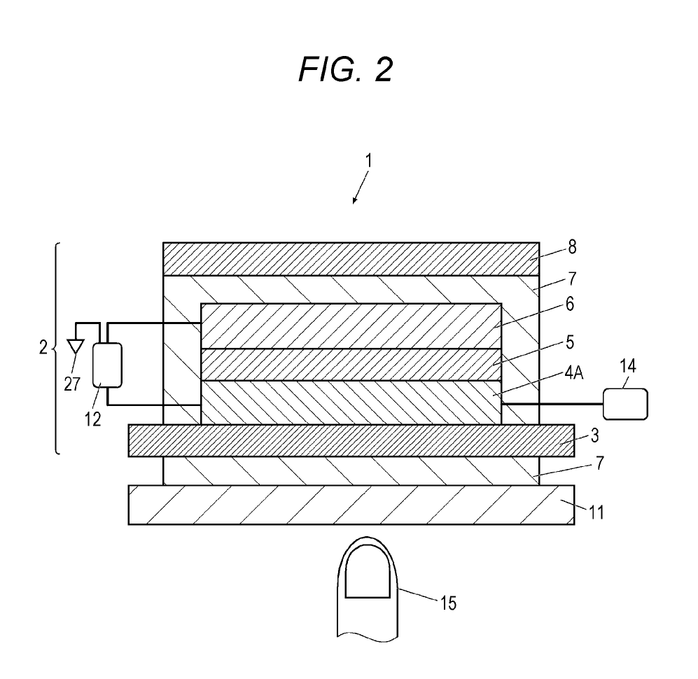

FIG. 2 is a schematic sectional view illustrating an example (first embodiment) in which in the configuration of the organic electroluminescence module of the present invention (the anode electrode is a detection electrode), the hovering detection circuit unit including the hovering detection circuit portion and the light emitting element driving circuit unit including a light emitting element driving circuit portion are connected to one common ground.

In the organic EL module (1) illustrated in FIG. 2, an anode electrode (4A, the positive electrode), and the same organic functional layer unit (5) as that of FIG. 1 are laminated on the transparent base material (3), and thus, the light emitting region is configured. The cathode electrode (6, the negative electrode) is laminated on the upper portion of the organic functional layer unit (5), and thus, the organic EL element is configured. The outer circumferential portion of the organic EL element is sealed with the adhesive agent (7) for sealing, and the sealing member (8) is disposed on the front surface thereof, and thus, the organic EL panel (2) is configured.

In addition, in the organic EL panel (2) according to the present invention, a metal foil layer may be disposed on the outermost surface side in order to protect the organic EL element.

In the configuration of FIG. 2, the anode electrode (4A, the positive electrode) is an electrode which functions as a facing electrode allowing the organic EL element to emit light, and has a function as the detection electrode. In the configuration illustrated in FIG. 2, the light emitting element driving circuit unit (12) controlling light emission is connected between the anode electrode (4A) and the cathode electrode (6).

The anode electrode (4A) further functions as the hovering detection electrode, and a hovering detection circuit unit (14) for detecting the approach of the finger (15) or the like is connected to the anode electrode (4A).

In the configuration illustrated in FIG. 2, the hovering detection circuit unit (14) and the light emitting element driving circuit unit (12) are connected to one common ground (27). Here, in FIG. 2, the illustration of wirings of the hovering detection circuit unit (14) and the ground (27) is omitted.

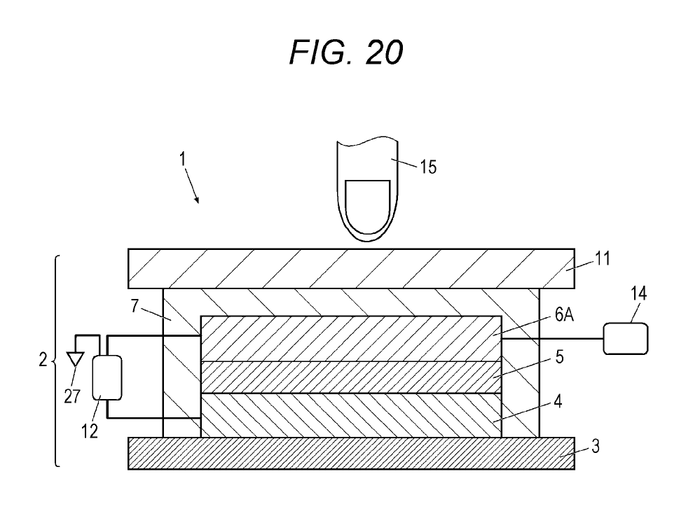

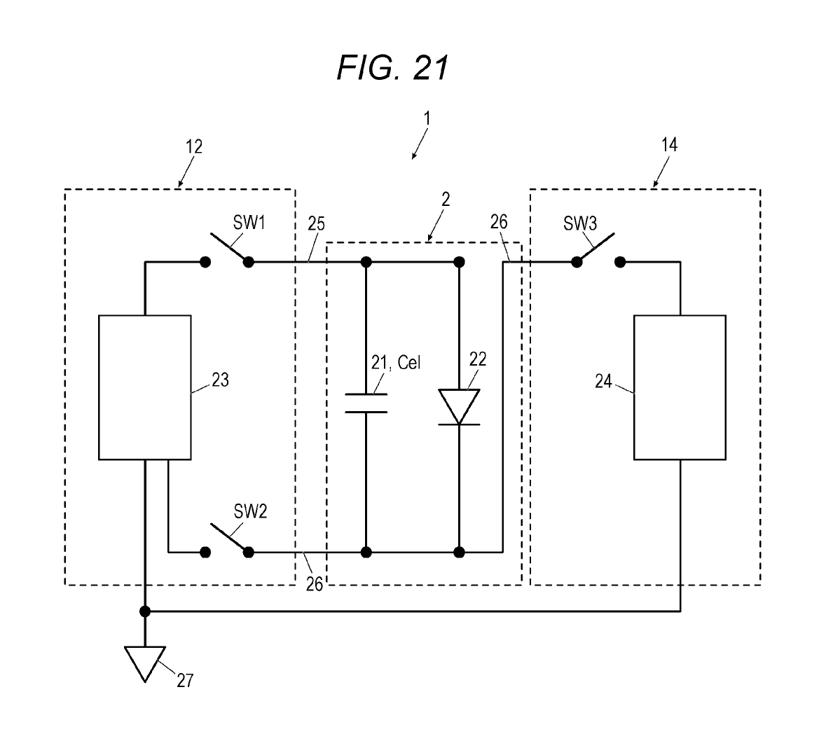

In FIG. 2, a configuration has been illustrated in which the anode electrode (4A) also functions as the hovering detection electrode, but as illustrated in FIG. 20 and FIG. 21 described below, the function may be applied to a cathode electrode (6A).

### Schematic Configuration of Organic Electroluminescence Module of Present Invention: Second Embodiment

Next, in the organic EL module of the present invention having a hovering detection function, another basic configuration (two grounds, second embodiment) will be described.

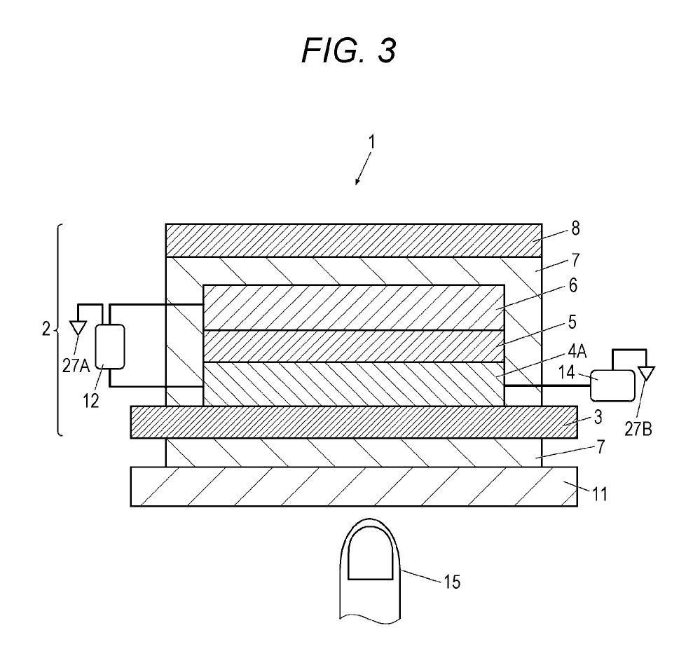

FIG. 3 is a schematic sectional view illustrating a configuration of the second embodiment including two grounds, in another configuration of the organic EL module of the present invention (the anode electrode is the detection electrode).

In the organic EL module (1) illustrated in FIG. 3, the anode electrode (4A, the positive electrode), and the same organic functional layer unit (5) as that of FIG. 2 are laminated on the transparent base material (3), and thus, the light emitting region is configured. The cathode electrode (6, the negative electrode) is laminated on the upper portion of the organic functional layer unit (5), and thus, the organic EL element is configured. The outer circumferential portion of the organic EL element is sealed with the adhesive agent (7) for sealing, and the sealing member (8) is disposed on the front surface thereof, and thus, the organic EL panel (2) is configured.

In addition, in the organic EL panel (2) according to the present invention, the metal foil layer may be disposed on a front surface side from the anode electrode (4A) or the cathode electrode (6) in order to protect the organic EL element.

In the configuration of FIG. 3, the anode electrode (4A, the positive electrode) is an electrode which functions as the facing electrode allowing the organic EL element to emit light, and has a function as the hovering detection electrode. In the configuration of FIG. 3, the light emitting element driving circuit unit (12) controlling light emission is connected between the anode electrode (4A) and the cathode electrode (6), and a ground (27A) is disposed on the light emitting element driving circuit unit (12).

The anode electrode (4A) further functions as the detection electrode, the hovering detection circuit unit (14) for detecting hovering (finger touch) is connected to the anode electrode (4A), and an independent ground (27B) is disposed on the hovering detection circuit unit (14).

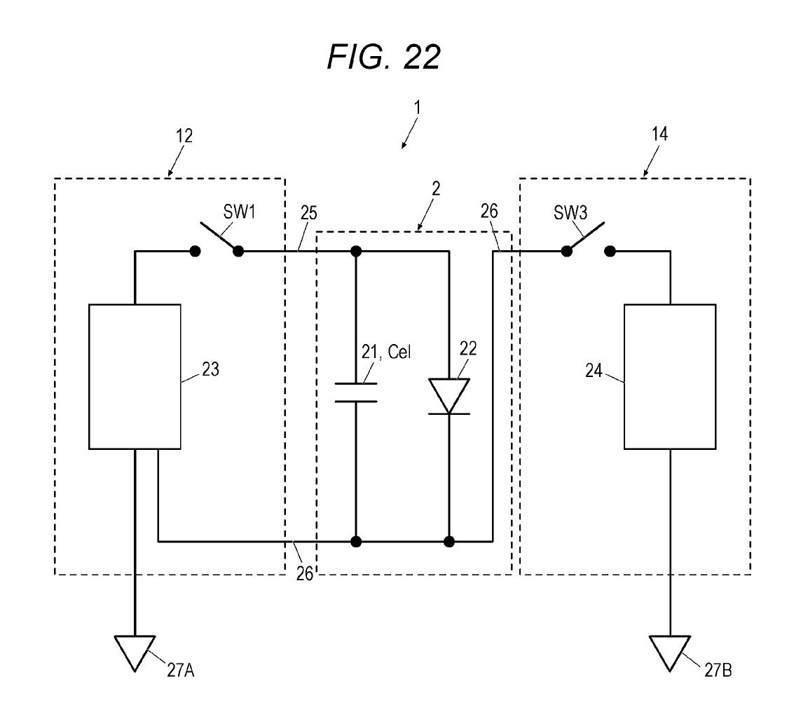

In FIG. 3, a configuration has been illustrated in which the anode electrode (4A) also functions as the detection electrode, but as illustrated in FIG. 22 described below, the function may be applied to the cathode electrode (6A).

[Outline of Hovering Detection]

First, the outline of hovering detection (proximity detection) in the organic EL module of the present invention will be described.

The hovering detection also referred to as proximity detection or three-dimensional touch panel detection, and is a method in which coordinate position information of the finger can be acquired even in a hovering state (a proximity state) where the finger is not in contact with a touch panel or the like.

Examples of the method in which hovering position information (proximity position information) of the finger can be acquired, are capable of including:

(1) an ultrasonic wave sensor system in which the finger is irradiated with an ultrasonic wave, and a coordinate position of the approaching finger is measured from a reflective wave thereof;

(2) an optical sensor type in-cell touch panel measuring the coordinates of the approaching finger from light receiving intensity of an optical sensor disposed in a display cell; and

(3) an electrostatic capacitance type touch panel measuring the coordinates of the approaching finger from a change amount in an electrostatic capacitance value on a touch panel, and

in the present invention, the hovering detection (the proximity detection) according to an electrostatic capacitance system, described in (3), is performed, from the viewpoint of being capable of obtaining the proximity position information in the entire touch panel, of being capable of obtaining the proximity position information in a constantly stable operation, and of not being necessary to add a novel device.

Next, an example of the hovering detection (the proximity detection) according to the electrostatic capacitance system will be described.

The hovering detection according to the electrostatic capacitance system is a method of detecting the approach of the finger with respect to the touch panel on the basis of electrostatic capacitance generated in one electrode (for example, an anode) of the touch panel, and the other electrode (for example, a cathode), and the ground.

In the electrostatic capacitance system, in the case of touch detection, a touch detection circuit detects contact by measuring the electrostatic capacitance generated between the finger and the hovering detection electrode. The finger has conductivity, and thus, the electrostatic capacitance is generated between the finger and the hovering detection electrode (including the cover glass). In general, in a case where areas of two conductor plates parallel to each other are set to S [m²], a distance between two conductor plates is set to D [m], and electric permittivity of a dielectric body filled between the two conductor plates is set to c, electrostatic capacitance C [F] generated between the two conductor plates is represented by Expression (1) described below.

C=(ε×S)/D Expression (1)

As represented in Expression (1) described above, the electrostatic capacitance (C) to be generated increases as the distance (D) between the two conductor plates decreases, and the electrostatic capacitance (C) to be generated decreases as the distance (D) between the two conductor plates increases. Therefore, the electrostatic capacitance (C) increases as a distance (D) between the finger and the hovering detection electrode decreases.

In a hovering detection circuit portion (24), the electrostatic capacitance (C) to be generated is measured. Then, in a case where the finger infinitely approaches the hovering detection electrode, and the distance (D) infinitely approaches 0, the value of the measured electrostatic capacitance (C) is greater than or equal to a threshold value Cth1 (a contact threshold value Cth1) set in advance. At this time, the hovering detection circuit portion determines that the finger sufficiently approaches (is in contact with) the hovering detection electrode to be considered that the finger is in contact with the hovering detection electrode through the cover glass. Further, the hovering detection electrode sets a position where the electrostatic capacitance of greater than or equal to the contact threshold value Cth1 is measured to a contact point, and outputs coordinates information of the contact point to the hovering detection circuit unit.

On the other hands, in a case where the user wears gloves or in a case where the user is in a hovering state, as represented in Expression (1), the electrostatic capacitance is generated even in a case where the hovering detection electrode is not in contact with the hovering detection electrode through the finger and the cover glass. Therefore, even in a case where the finger is in a non-contact hovering state with respect to the hovering detection electrode through the cover glass, it is possible to sense the approach of the finger by decreasing the value of the contact threshold value Cth1. Thus, even in the non-contact state, the hovering detection circuit portion (24) is capable of detect the approaching finger from the hovering detection electrode with a certain interval. Thus, a function of detecting the approach of the finger even in the case of not being in contact with a cover glass screen of the hovering detection electrode is referred to as a hovering function.

In the hovering function, a threshold value of the electrostatic capacitance which is generated in a state of “approaching to a certain extent” can be set in advance as an approach threshold value Cth2 (<Cth1). That is, in a case where the measured electrostatic capacitance (C) is less than the contact threshold value Cth1 but is greater than or equal to the approach threshold value Cth2, the finger (15) is not in contact with a hovering detection electrode portion through the cover glass (11), but is in a state of approaching with a certain interval. At this time, a hovering detection unit is capable of determining that the finger is not in contact with the hovering detection electrode through the cover glass, but approaches to a certain extent.

For example, a method described in JP 2009-543246 A, JP 2010-231565 A, JP 2013-80290 A, JP 2014-99189 A, JP 2014-132441 A, JP 2014-157402 A, JP 2014-229302 A, and the like can be suitably selected and adopted as a specific control method relevant to the hovering detection.

[Driving Circuit of Organic EL Module]

Next, a driving circuit of the organic EL module of the present invention and a driving method thereof will be described.

### Representative Driving Circuit Diagram of First Embodiment

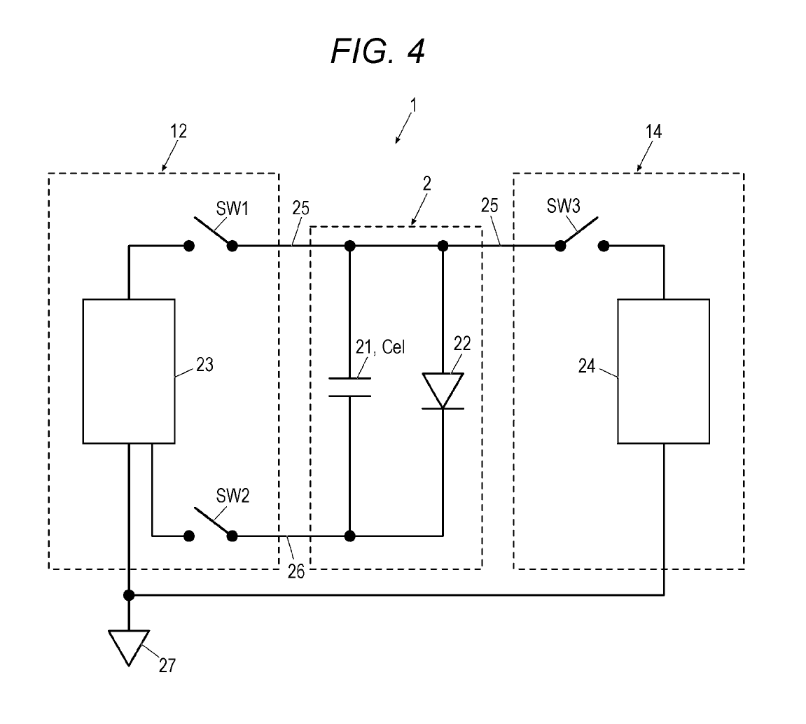

FIG. 4 is a driving circuit diagram illustrating an example of a circuit configuration driving of the first embodiment of the organic EL module illustrated in FIG. 2.

In the circuit diagram of the organic EL module (1) illustrated in FIG. 4, the organic EL panel (2) illustrated in a center broken line includes anode electrode wiring (25) and cathode electrode wiring (26), the organic EL element (22), which is a diode, and a capacitor (21, Cel) are connected between both of the wirings.

In the light emitting element driving circuit unit (12) on a left side, the anode electrode wiring (25) drawn from the anode electrode is connected to a light emitting element driving circuit portion (23) through a switch 1 (SW1), and the cathode electrode wiring (26) drawn from the cathode electrode is connected to the light emitting element driving circuit portion (23) through a switch 2 (SW2). In addition, the light emitting element driving circuit portion (23) is connected to the ground (27). Specifically, the ground (27) is referred to as a signal ground.

<Light Emitting Element Driving Circuit Unit>

In the light emitting element driving circuit unit (12), a constant current driving circuit or a constant voltage driving circuit are embedded, a light emitting timing of the organic EL element is controlled, and as necessary, the light emitting element driving circuit portion (23) of being capable of applying reverse bias (a reverse applied voltage) is provided. In addition, in

FIG. 4, the light emitting element driving circuit portion (23), and SW1 and SW2 are each independently configured, and as necessary, may be configured by embedding the switch 1 (SW1) and/or the switch 2 (SW2) in the light emitting element driving circuit portion (23).

In the present invention, the light emitting element driving circuit unit (12), as illustrated by a broken line of FIG. 4, represents a circuit range configured of the anode electrode wiring (25), SW1, the light emitting element driving circuit portion (23), SW2, and the cathode electrode wiring (26).

The light emitting element driving circuit portion (23) according to the present invention is not particularly limited to such a configuration, and various light emitting element driving circuit portions (organic EL element driving circuits) known from the related art can be applied. In general, the light emitting element driving circuit, for example, has a function of applying a current according to a light emission amount of the organic EL element, which is the light emitting element, between the anode electrode and the cathode electrode, according to a light emitting pattern of the light emitting element, set in advance as illustrated in FIG. 4. A constant current circuit formed of a boosting type or dropping type DC-DC converter circuit, a feedback circuit of a current value, a switch control circuit of a DC-DC converter, and the like is known as the light emitting element driving circuit, and it is possible to refer to a light emitting element driving circuit described in JP 2002-156944 A, JP 2005-265937 A, JP 2010-040246 A, and the like.

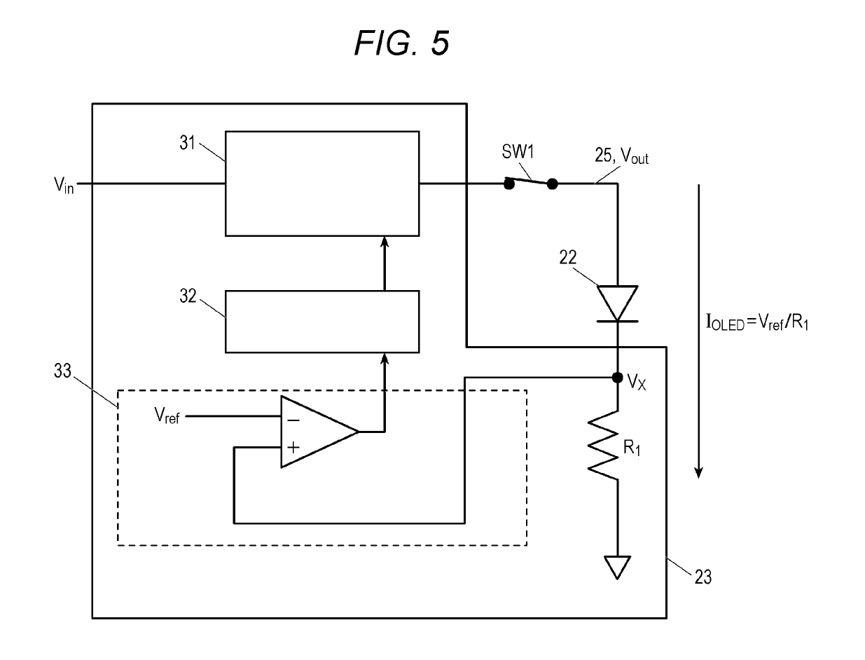

Hereinafter, a specific configuration of the light emitting element driving circuit portion will be described by using FIG. 5.

FIG. 5 is a schematic circuit diagram illustrating an example of the configuration of the light emitting element driving circuit unit which is capable of being applied to the present invention.

In FIG. 5, the light emitting element driving circuit portion (23) includes a boosting type or dropping type DC-DC converter circuit (31), a switch element control circuit (32) of the DC-DC converter, and a feedback circuit (33) having a current value. For example, in a case where detection resistance is set to R₁, and a comparative potential is set to V_{ref}, an anode potential of the organic EL element (22) can be boosted or dropped by the DC-DC converter circuit (31) such that a current I_{OLED} flowing into the organic EL element (22), which is a diode is V_{ref}/R₁, and thus, the constant current circuit can be obtained. Here, the feedback circuit (33) performs feedback with respect to output Vₒᵤₜ of the DC-DC converter circuit (31) such that V_{X}=V_{ref} is obtained. For example, in the case of V_{ref}=0.19 V and R₁=100Ω, Vₒᵤₜ is adjusted by the DC-DC converter circuit (31) such that Constant Current Value V_{ref}/R₁=1.9 mA is obtained.

<Hovering Detection Circuit Unit>

On the other hand, the hovering detection circuit unit (14) on a right side connects the anode electrode wiring (25) drawn from the anode electrode which functions as the hovering detection electrode, to the hovering detection circuit portion (24) through a switch 3 (SW3), and the hovering detection circuit portion (24) is connected to the ground (27). The switch 3 (SW3) may be embedded in the hovering detection circuit portion (24).

In addition, the hovering detection circuit portion (24) is not particularly limited to such a configuration, and a known hovering detection circuit portion of the related art can be applied. In general, the hovering detection circuit is configured of an amplifier, a filter, an AD converter, a rectification smoothing circuit, a comparator, and the like, and a representative example of the hovering detection circuit is capable of including a self-capacitance detection system, a series capacitance partial pressure comparison system (Omron system), and the like, and it is possible to refer to a hovering detection circuit described in JP 2009-543246 A, JP 2010-231565 A, JP 2012-073783 A, JP 2013-088932 A, JP 2013-80290 A, JP 2014-053000 A, JP 2014-99189 A, JP 2014-132441 A, JP 2014-157402 A, JP 2014-229302 A, and the like.

The switch 1 and the switch 3 (SW1 and SW3) may have a switch function of an electric field effect transistor (FET), a thin film transistor (TFT), and the like, and are not particularly limited.

### Representative Driving Circuit Diagram of Second Embodiment

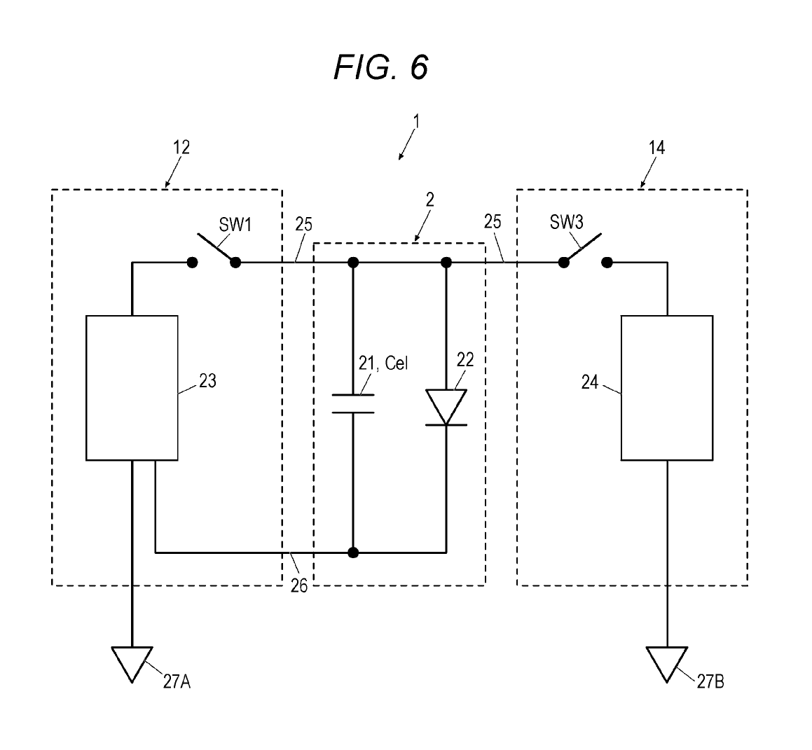

FIG. 6 is a driving circuit diagram of the second embodiment in which the hovering detection circuit unit, which is an example of the organic EL module, and the light emitting element driving circuit unit are each independently connected to the ground.

In the circuit diagram of the organic EL module (1) illustrated in FIG. 6, the configurations of the organic EL panel (2) illustrated in the center, the light emitting element driving circuit unit (12), and the hovering detection circuit unit (14) are respectively identical to those in the first embodiment described in FIG. 4 described above.

In the second embodiment, the ground (27A) is independently connected to the optical element driving circuit unit (12), and the independent ground (27B) is disposed with respect to the hovering detection circuit unit (14).

[Driving Method of Organic EL Module]

(Driving Method 1 in First Embodiment)

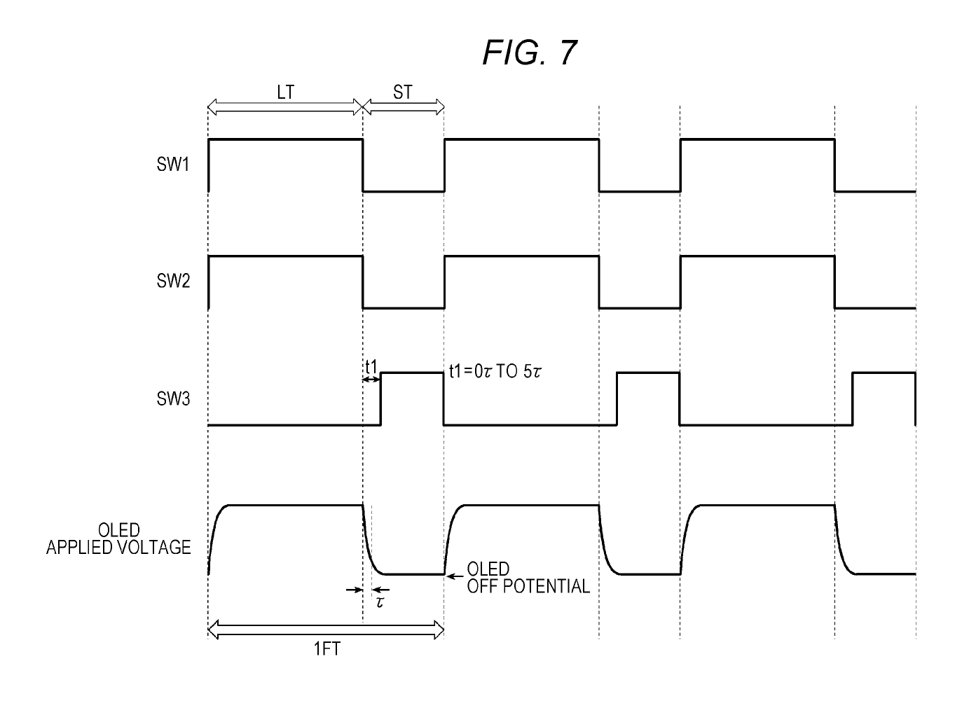

FIG. 7 is a timing chart illustrating an example of a light emitting period and a sensing period of the first embodiment.

In the organic EL module (1) of the first embodiment having the circuit configuration illustrated in FIG. 4, ON/OFF of each of switches is controlled, the light emitting period of the organic EL panel which is controlled by the light emitting element driving circuit unit (12) and the hovering sensing period which is controlled by the hovering detection circuit unit (14) are separately driven, and thus, it is possible to express the hovering sensor function performed in the light emitting display unit.

An upper portion of FIG. 7 is a graph illustrating an operation timing of ON/OFF of SW1 in the light emitting element driving circuit unit (12), and similarly, a lower portion illustrates an operation timing of SW2 and SW3. Here, in the graph, a high period represents an ON state of the switch. The same applies to a timing chart diagram described below.

The lowermost graph is a graph illustrating the history of an applied voltage with respect to the organic EL element (OLED), and in a case where SW1 and SW2 are in a state of “ON”, a voltage increases from an OLED OFF voltage, and light emission is started at a time point where a voltage necessary for light emission is obtained. Next, in a case where SW1 and SW2 are turned “OFF”, the supply of a current to the OLED is stopped, and the OLED is turned off. However, even in a case where SW1 and SW2 are turned “OFF”, the OLED is not instantaneously turned off, and it takes a certain period of time to be turned off according to a constant τ at the time of charging and discharging an OLED.

On the other hand, SW3 is a switch controlling the driving of the hovering detection circuit unit (14), and in a case where SW1 and SW2 are in a state of “ON”, SW3 is in a state of “OFF”, and is turned “ON” after SW1 and SW2 are turned “OFF”, and thus, performs the hovering detection. Here, a timing where SW3 is turned “ON” is set after SW1 and SW2 are turned “OFF”, and then, predetermined standby time (t) elapses. It is preferable that a standby period (t) is in a range of approximately 0τ to 5τ of the constant τ at the time of charging and discharging an OLED.

In the timing chart illustrated in FIG. 7, a period until SW1 and SW2 are turned “ON”, and then, are turned “OFF” is a light emitting period (LT), a period until SW1 and SW2 are turned “OFF”, the standby time (t) elapses, SW3 is turned “ON”, and the hovering detection is performed, and then, is turned “OFF” is a sensing period (ST), and LT+ST is referred to as one frame period (1FT).

The light emitting period (LT), the sensing period (ST), and one frame period (1FT) in the organic EL module of the present invention are not particularly limited, but a condition suitable for the environment to be applied can be suitably selected, and as an example, it is preferable that the light emitting period (LT) of the OLED is in a range of 0.1 msec. to 2.0 msec., the sensing period (ST) is in a range of 0.05 msec. to 0.3 msec., and one frame period (1FT) is in a range of 0.15 msec. to 2.3 msec. In addition, it is preferable that one frame period (1FT) is longer than or equal to 60 Hz from the viewpoint of reducing flicker.

(Driving Method 2 in the First Embodiment)

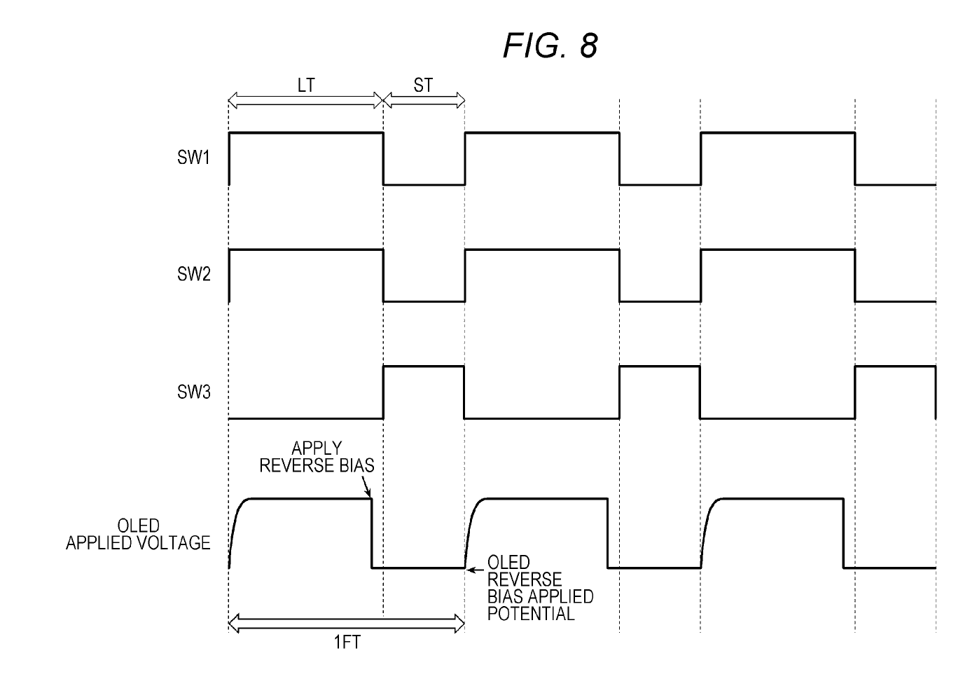

FIG. 8 is a timing chart illustrating another example (applying a reverse bias voltage to the OLED) of the light emitting period and the sensing period of the driving circuit (first embodiment) illustrated in FIG. 4.

In FIG. 8, the reverse applied voltage (the reverse bias voltage) is applied between the anode electrode and the cathode electrode immediately before SW1 and SW2 are turned “ON”, and then, are turned to “OFF” at the end of the light emitting period (LT), with respect to an OLED applied voltage pattern illustrated in FIG. 7, and thus, in a timing chart where charge and discharge at the time of turning off the OLED are suppressed, it is not necessary to provide the standby time (t) as illustrated in FIG. 7, as a pattern of SW3.

(Circuit Driving of Light Emitting Period of the First Embodiment)

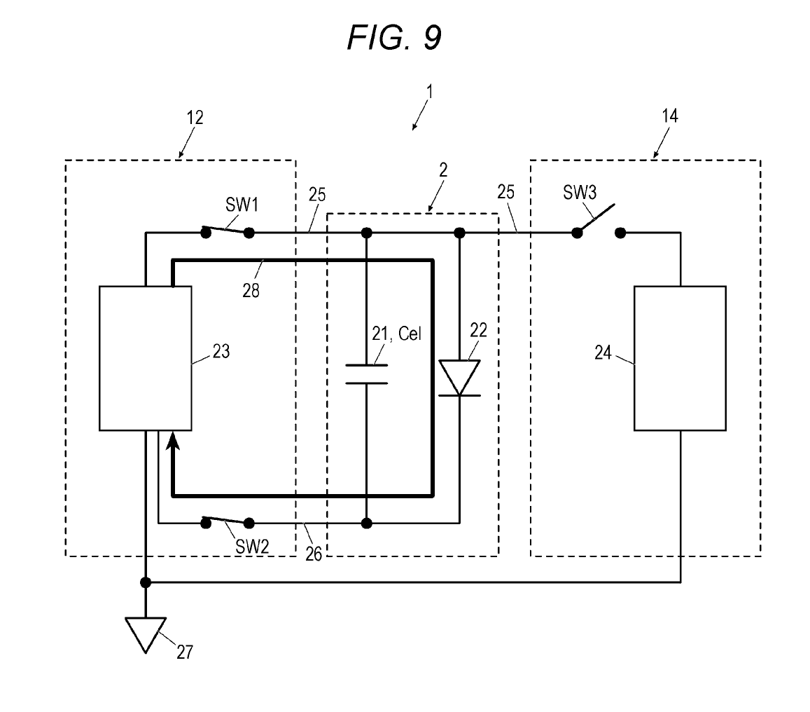

FIG. 9 is a circuit operating chart illustrating an example of the operation of the circuit during the light emitting period (LT) of the first embodiment.

In the first embodiment, SW1 and SW2 are in a state of “ON”, a light emitting condition is controlled by the light emitting element driving circuit portion (23), and the organic EL element (22) emits light according to a light emitting control information route (28), during the light emitting period (LT).

At this time, SW3 of the hovering detection circuit unit (14) is in a state of “OFF”.

### Circuit Driving of Sensing Period of First Embodiment

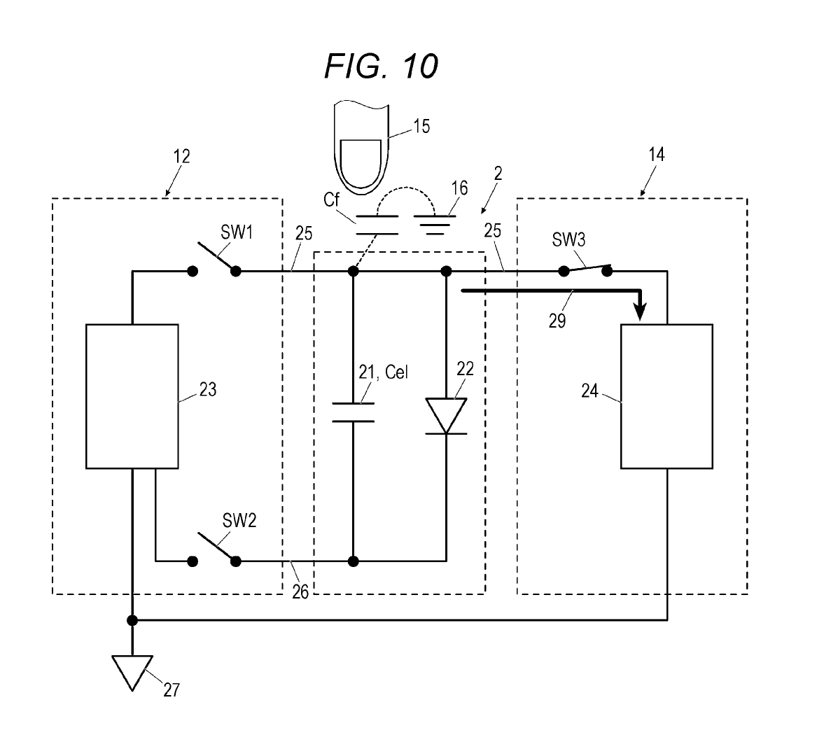

FIG. 10 is a circuit operating chart illustrating an example of the circuit operation during the sensing period (ST) of the first embodiment.

In FIG. 10, the finger (15) hovers in a glass substrate upper surface portion of the anode electrode wiring (25) including the anode electrode (4), which is the detection electrode configuring the organic EL panel (2), in a state where SW1 and SW2 of the light emitting element driving circuit unit (12) are turned “OFF”, the light emitting element driving circuit is opened, and the switch 3 (SW3) of the hovering detection circuit unit (14) is turned “ON”, and thus, the electrostatic capacitance Cf is generated between the finger (15) and the anode electrode (4), which is the detection electrode. The electrostatic capacitance Cf is connected to an earth. “29” is a hovering detection information route at the time of sensing.

At this time, SW1 and SW2 are in a state of “OFF”, and the pair of electrodes are in a state of a floating potential where the electric capacitance of the organic EL panel is not detected, and thus, the electrostatic capacitance is in a state of Cf>Cel, and the hovering detection can be performed.

### Circuit Driving of Sensing Period of Second Embodiment

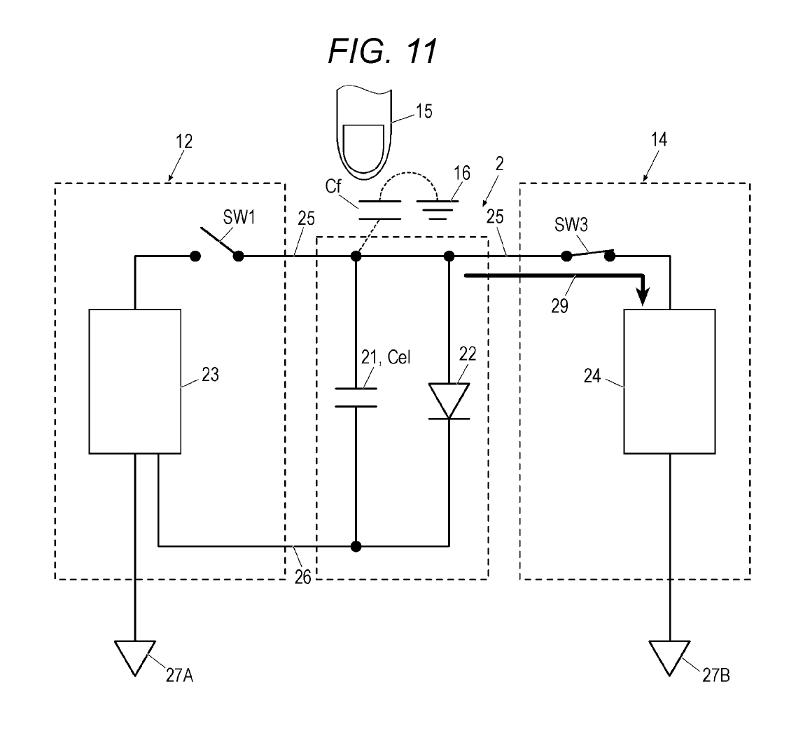

FIG. 11 is a circuit operating chart illustrating an example of the operation of the circuit during the sensing period (ST) of the second embodiment (two grounds).

In FIG. 11, the finger (15) hovers in the glass substrate upper surface portion of the anode electrode wiring (25) including the anode electrode (4), which is the detection electrode configuring the organic EL panel (2) in a state where SW1 of the light emitting element driving circuit unit (12) is turned “OFF”, the light emitting element driving circuit is opened, and the switch 3 (SW3) of the hovering detection circuit unit (14) is turned “ON”, and thus, the electrostatic capacitance Cf is generated between the finger (15) and the anode electrode (4), which is the detection electrode. The electrostatic capacitance Cf is connected to the earth (16). “29” is the hovering detection information route at the time of sensing.

At this time, SW1 is in a state of “OFF”, and the pair of electrodes are in a state of a floating potential where the electric capacitance of the organic EL panel is not detected, and thus, the electrostatic capacitance is in a state of Cf>Cel, and the hovering detection can be performed.

[Circuit Diagram of Other Organic EL Modules]

### Third Embodiment: Use Capacitor Instead of SW3

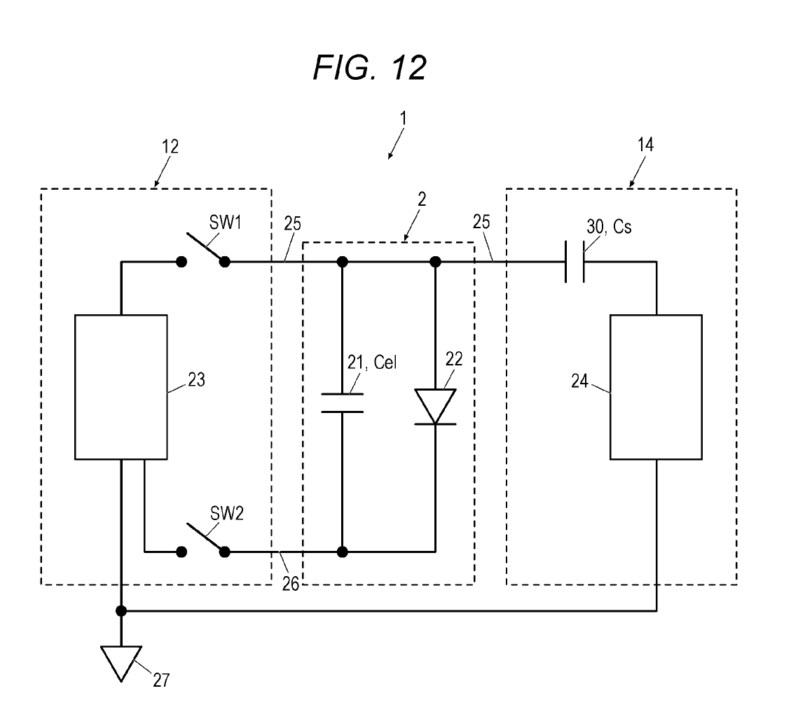

A capacitor Cs (30) is incorporated in a third embodiment illustrated in FIG. 12, instead of the switch (SW3) configuring the hovering detection circuit unit (14) with respect to the driving circuit of the first embodiment illustrated in FIG. 4. The capacitor Cs (30) is incorporated in the circuit, and thus, it is possible to apply the same function as that of the switch 3 (SW3).

At this time, the switch 1 (SW1) and/or the switch 2 (SW2) may be embedded in light emitting element driving circuit portion (23). In addition, the capacitor Cs (30) may be embedded in the hovering detection circuit portion (24).

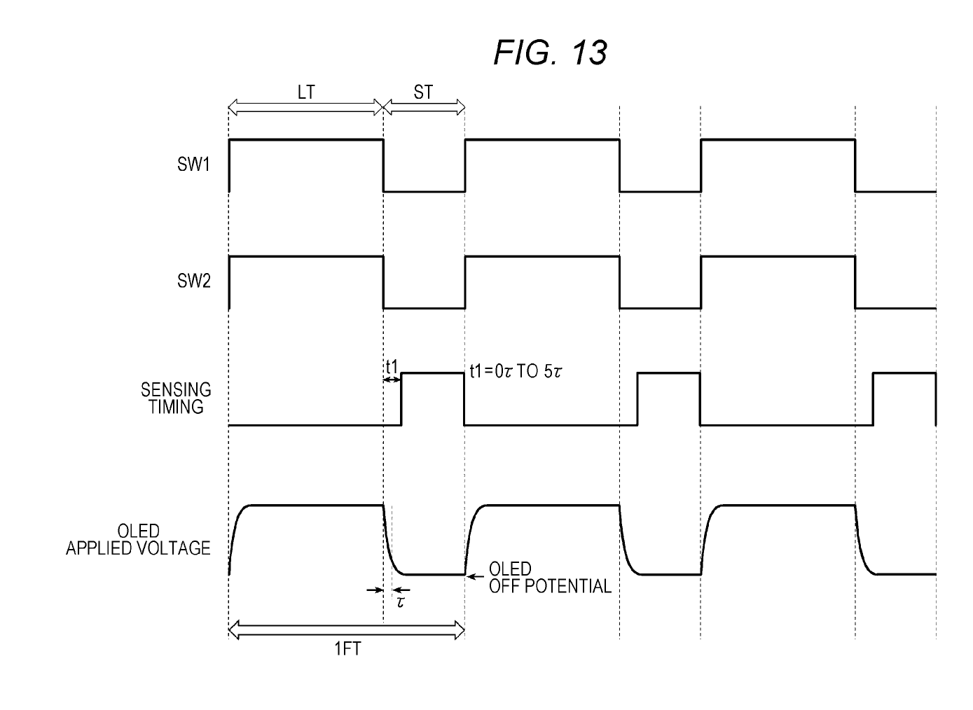

FIG. 13 is an example of a light emitting period and a sensing period of the third embodiment illustrated in FIG. 12, and is a timing chart in which the standby time (t) is provided as a sensing timing.

First, the timing chart illustrated in FIG. 13 is a diagram illustrating a sensing timing of the capacitor Cs (30) instead of the “ON/OFF” operation of SW3, with respect to the timing chart illustrated in FIG. 7.

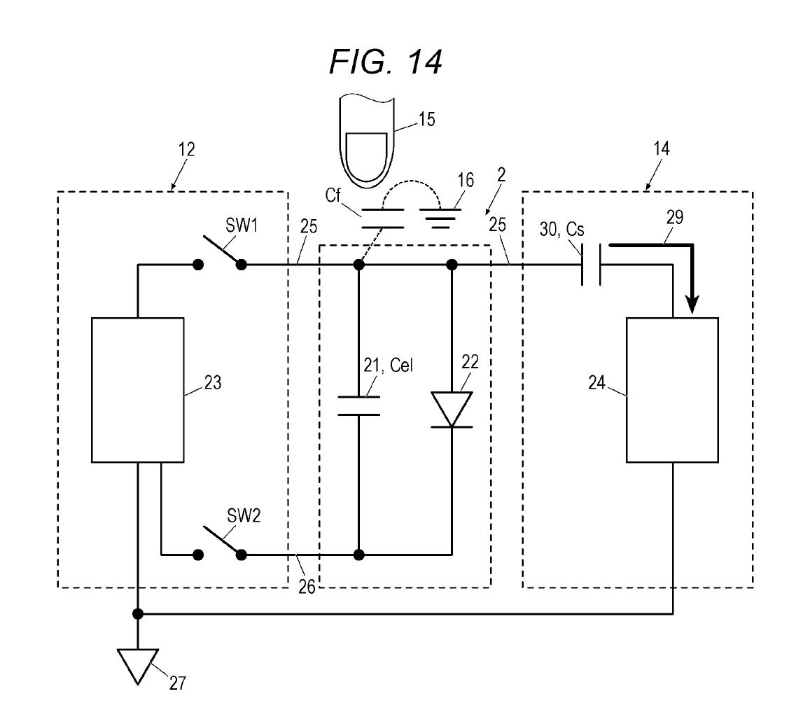

FIG. 14 is a circuit operating chart illustrating an example of the circuit operation during the sensing period (ST) of the third embodiment, and is a method in which the finger (15) hovers in the glass substrate upper surface portion of the anode electrode wiring (25) including the anode electrode (4), which is the detection electrode in a state in which SW1 and SW2 of the light emitting element driving circuit unit (12) are turned “OFF”, and the light emitting element driving circuit is opened, and thus, the electrostatic capacitance Cf is generated between the finger (15) and the anode electrode (4), which is the detection electrode, and the hovering detection is performed according to the electrostatic capacitance.

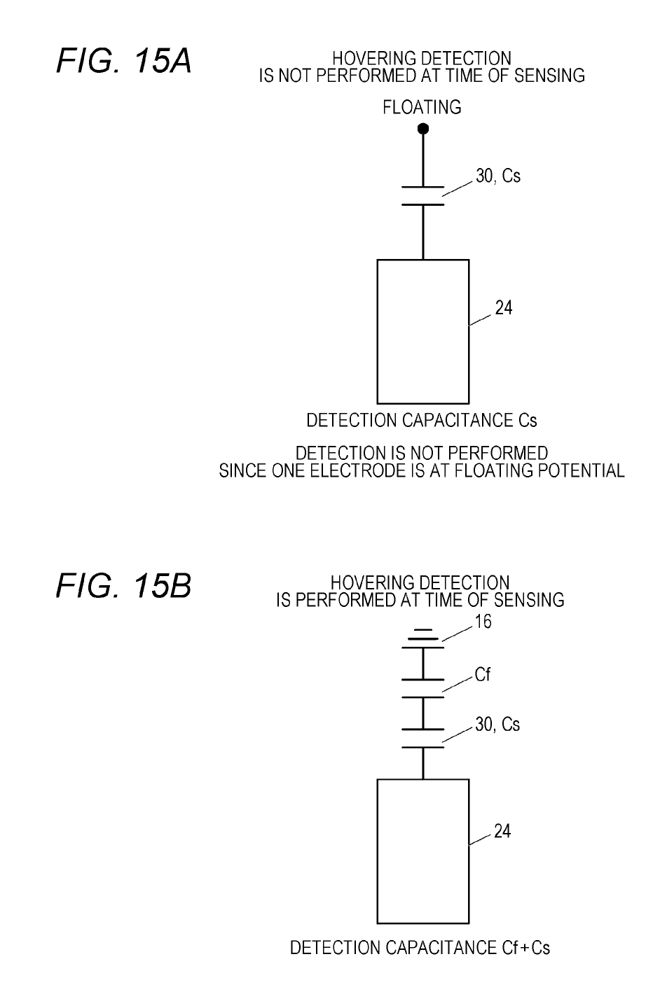

FIG. 15A and FIG. 15B are schematic views for illustrating an electrostatic capacitance difference in the presence or absence of finger touch of the sensing period (at the time of the hovering detection) of the third embodiment, and as illustrated in FIG. 15A, in a state where there is no finger touch, one electrode is in a state of a floating potential, and thus, capacitance Cs provided in the hovering detection circuit unit (14) is not detected. In contrast, at the time of the hovering detection (the finger touch) illustrated in FIG. 15B, the total value of the electrostatic capacitances Cf and Cs generated between the finger (15) and the anode electrode (4), which is the hovering detection electrode, is the electrostatic capacitance, and thus, the hovering can be detected.

### Fourth Embodiment

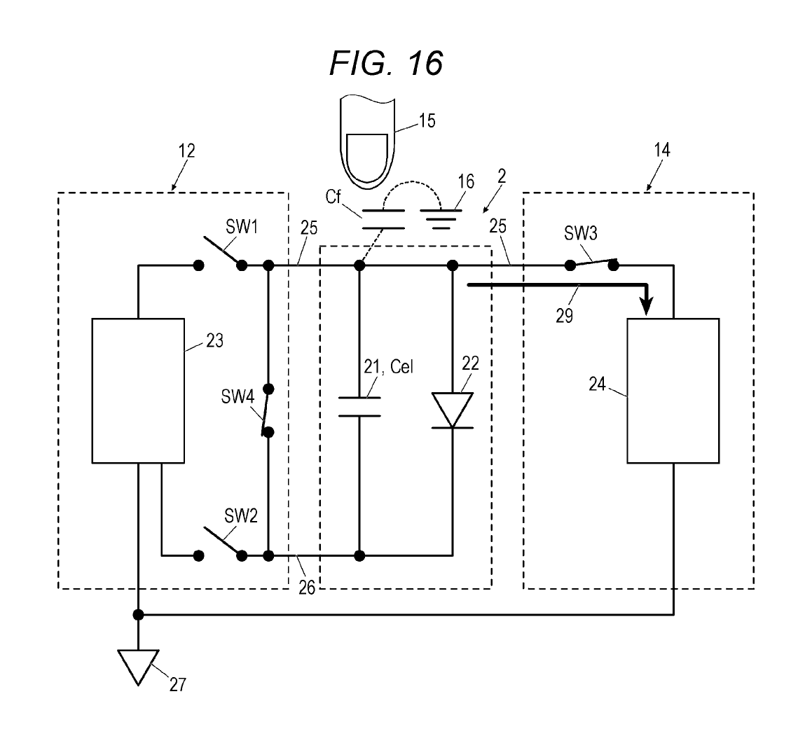

FIG. 16 is a circuit operating chart illustrating an example of the circuit operation during the sensing period of a fourth embodiment, which is another example of the organic EL module (one ground).

In the organic EL module (1) of the fourth embodiment, which has the configuration illustrated in FIG. 16, a basic driving circuit configuration is identical to the configuration of the driving circuit of FIG. 4 described above, and a fourth switch 4 (SW4) for short-circuiting the anode electrode wiring (25) and the cathode electrode wiring (26) is provided.

At this time, the switch 1 (SW1) and/or the switch 2 (SW2) may be embedded in the light emitting element driving circuit portion (23). In addition, the switch 3 (SW3) may be embedded in the hovering detection circuit portion (24).

In a configuration including SW4 illustrated in FIG. 16, at the moment of fully turning SW1 and SW2 “ON”, of allowing the OLED to emit light, and of proceeding to the sensing period (ST) during the light emitting period (LT), SW1 and SW2 are turned “OFF”, and SW3 and SW4 are turned “ON”. The SW4, which is a short switch, is turned “ON”, and thus, charge and discharge components remaining between the electrodes of the OLED are instantaneously removed, and therefore, it is possible to proceed to the sensing period (ST) from the light emitting period (LT) without providing the standby time (t).

FIG. 16 is a circuit operating chart illustrating an example of the circuit operation during the sensing period of the fourth embodiment, and is a method in which the finger (15) hovers in the glass substrate upper surface portion of the anode electrode wiring (25) including the anode electrode (4), which is the detection electrode, in a state where SW1 and SW2 of the light emitting element driving circuit unit (12) are turned “OFF”, and the light emitting element driving circuit is opened, and thus, the electrostatic capacitance Cf is generated between the finger (15) and the anode electrode (4), which is the hovering detection electrode, and the hovering detection is performed according to the electrostatic capacitance. At this time, the switch 4 (SW4) in the light emitting element driving circuit unit (12) is simultaneously set to be in a state of “ON”, and thus, charge and discharge between the facing electrodes can be instantaneously performed.

### Fifth Embodiment

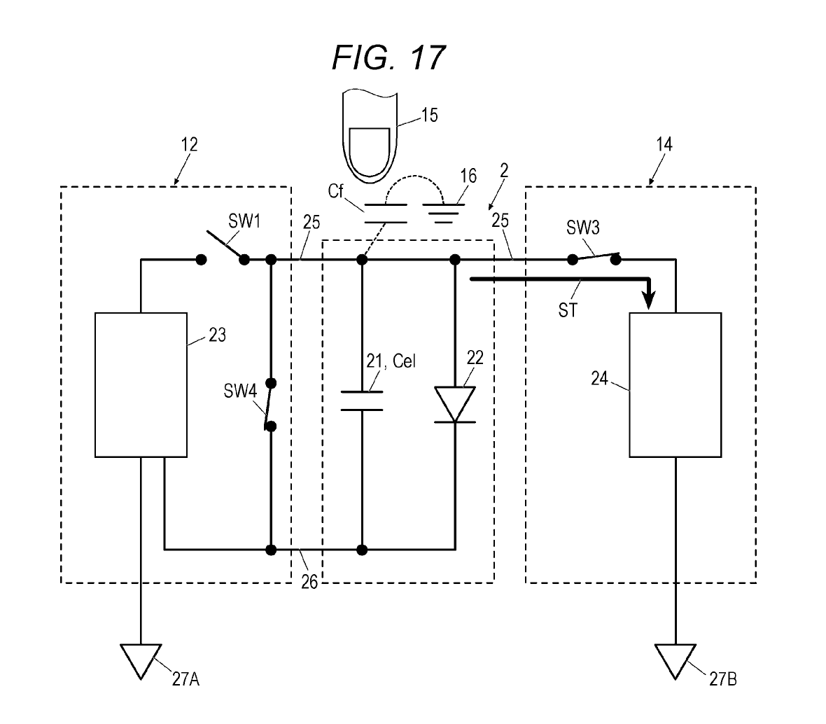

FIG. 17 illustrates a configuration in which two grounds are provided with respect to FIG. 16, is a method in which is the finger (15) hovers in the glass substrate upper surface portion of the anode electrode wiring (25) including the anode electrode (4), which is the detection electrode, in a state where SW1 of the light emitting element driving circuit unit (12) is turned “OFF”, and the light emitting element driving circuit is opened, and thus, the electrostatic capacitance Cf is generated between the finger (15) and the anode electrode (4), which is the hovering detection electrode, and the hovering detection is performed according to the electrostatic capacitance. At this time, the switch 4 (SW4) in the light emitting element driving circuit unit (12) is simultaneously set to be in a state of “ON”, and thus, charge and discharge between the facing electrodes can be instantaneously performed.

### Sixth Embodiment

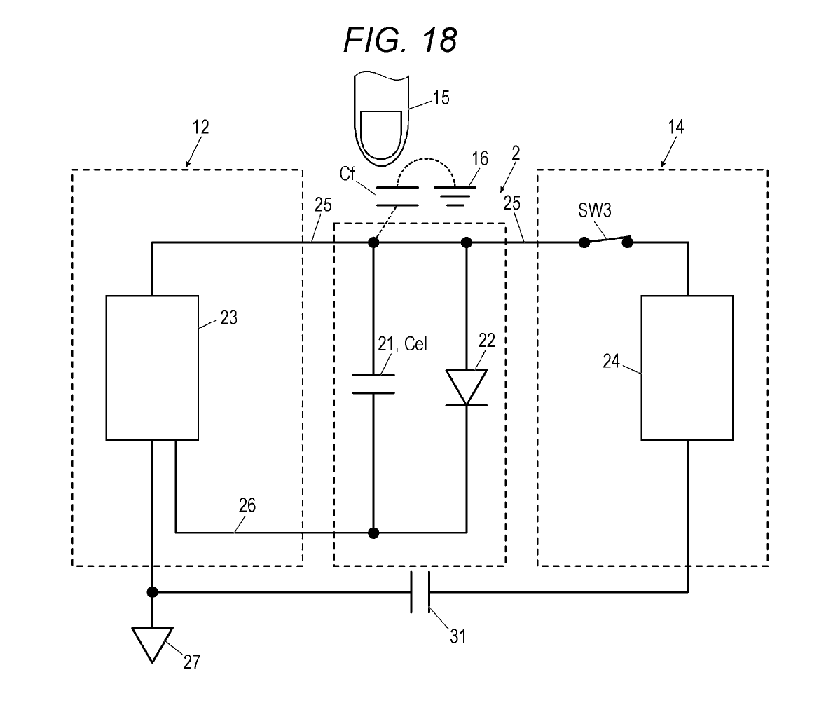

In a sixth embodiment illustrated in FIG. 18, a circuit operating chart illustrates an example of the circuit operation during the sensing period of a system in which the organic EL module has one ground, and the OLED constantly emits light.

In the organic EL module (fourth embodiment) illustrated in FIG. 18, a driving circuit diagram at the time of the proximity detection is exemplified as an example of a driving system in which the organic EL panel which is controlled by the light emitting element driving circuit portion continuously emits light, and the hovering sensing period which is controlled by the hovering detection circuit portion periodically appears. Specifically, the capacitor (31) is provided between the wirings connecting the grounds of the light emitting element driving circuit portion (23) and the hovering detection circuit portion (24) together.

In FIG. 18, a switch does not exist on the light emitting element driving circuit unit (12) side, and thus, the circuits are in a state of being constantly connected to each other, and the organic EL element (22) continuously emits light. On the other hand, in the hovering detection circuit unit (14) on a right side, the anode electrode wiring (25) drawn out from the anode electrode which functions as the hovering detection electrode is connected to the hovering detection circuit portion (24) through the switch 3 (SW3), and the hovering detection circuit portion is connected to the ground (27) through the capacitor (31) on the way.

In FIG. 18, SW3 of the hovering detection circuit unit (14) is in a state of “ON”, and the finger (15) hovers in the glass substrate upper surface portion of the anode electrode wiring (25) including the anode electrode (4), which is the detection electrode configuring the organic EL panel (2), and thus, the electrostatic capacitance Cf is generated between the finger (15) and the anode electrode (4), which is the detection electrode, and the hovering can be detected.

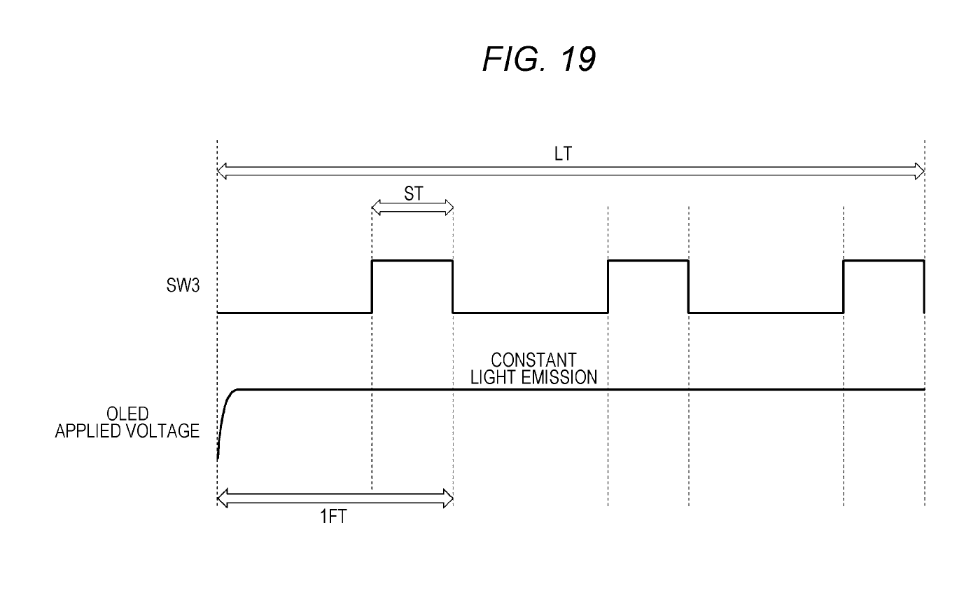

FIG. 19 is a timing chart configured of a light emitting period (ST) of continuously emitting light and an intermittent sensing period (ST) in the sixth embodiment, the circuits are in a state of being constantly connected to each other without having SW1 and SW2 as illustrated in FIG. 7 described above, and thus, as illustrated in the lower portion, the OLED applied voltage is constantly in a state of “ON”, and light emission is constantly performed. In contrast, SW3 of the hovering detection circuit unit (14) is turned “ON/OFF”, and thus, the hovering detection (ST) can be periodically performed.

[Cathode Electrode is Hovering Detect Electrode]

In FIG. 2 to FIG. 19, an example is illustrated in which the hovering detection electrode is set to the anode electrode (the positive electrode), but the cathode electrode (the negative electrode) can be set to the hovering detection electrode.

A configuration illustrated in FIG. 20 illustrates another configuration of the organic EL module of the present invention, and is a schematic sectional view illustrating an example in which the cathode electrode is the hovering detection electrode.

The hovering detection electrode illustrated in FIG. 2 to FIG. 19 is the anode electrode (the positive electrode), but in the configuration of FIG. 20, the cathode electrode (6A) is provided as the hovering detection electrode, and the hovering detection circuit unit (14) is connected to the cathode electrode (6A), and thus, a surface on the cathode electrode (6A) side is a hovering detection surface of the finger touch.

### Seventh Embodiment

FIG. 21 is an example of a configuration in which the organic EL module has one ground, is a driving circuit diagram of a seventh embodiment in which the cathode electrode is the hovering detection electrode, and is a diagram in which the wiring of the hovering detection circuit unit (14) is formed of the cathode electrode wiring (26) with respect to the driving circuit diagram of the first embodiment illustrated in FIG. 4, and the other configurations are completely identical to those of FIG. 4 or the like.

### Eighth Embodiment

FIG. 22 is an example of a configuration in which the organic EL module has two grounds, is a driving circuit diagram of an eighth embodiment in which the cathode electrode is the hovering detection electrode, and a diagram in which the wiring of the hovering detection circuit unit (14) is formed of the cathode electrode wiring (26) with respect to the driving circuit diagram of the second embodiment illustrated in FIG. 6, and the other configurations are completely identical to those of FIG. 6 or the like.

<<Configuration of Organic Electroluminescence Panel>>

In the organic EL panel (2) configuring the organic EL module (1), for example, as exemplified in FIG. 2, the anode electrode (4, the positive electrode) and the organic functional layer unit (5) are laminated on the transparent base material (3), and the cathode electrode (6, the negative electrode) is laminated on the upper portion of the organic functional layer unit (5), and thus, the organic EL element including the light emitting region is configured. The outer circumferential portion of the organic EL element is sealed with the adhesive agent (7) for sealing, and the sealing member (8) is disposed on the front surface thereof, and thus, the organic EL panel (2) is configured.

Hereinafter, a representative example of the configuration of the organic EL element will be described.

(i) Positive Electrode/Hole Injecting and Transporting Layer/Light Emitting Layer/Electron Injecting and Transporting Layer/Negative Electrode

(ii) Positive Electrode/Hole Injecting and Transporting Layer/Light Emitting Layer/Hole Inhibiting Layer/Electron Injecting and Transporting Layer/Negative Electrode

(iii) Positive Electrode/Hole Injecting and Transporting Layer/Electron Inhibiting Layer/Light Emitting Layer/Hole Inhibiting Layer/Electron Injecting and Transporting Layer/Negative Electrode

(iv) Positive Electrode/Hole Injecting Layer/Hole Transporting Layer/Light Emitting Layer/Electron Transporting Layer/Electron Injecting Layer/Negative Electrode

(v) Positive Electrode/Hole Injecting Layer/Hole Transporting Layer/Light Emitting Layer/Hole Inhibiting Layer/Electron Transporting Layer/Electron Injecting Layer/Negative Electrode

(vi) Positive Electrode/Hole Injecting Layer/Hole Transporting Layer/Electron Inhibiting Layer/Light Emitting Layer/Hole Inhibiting Layer/Electron Transporting Layer/Electron Injecting Layer/Negative Electrode

Further, an interlayer having non-light emitting properties may be disposed between the light emitting layers. The interlayer may be a charge generating layer, or may have a multiphoton unit configuration.

Examples of the detailed configuration of the organic EL element which can be applied to the present invention are capable of including configurations described in JP 2013-157634 A, JP 2013-168552 A, JP 2013-177361 A, JP 2013-187211 A, JP 2013-191644 A, JP 2013-191804 A, JP 2013-225678 A, JP 2013-235994 A, JP 2013-243234 A, JP 2013-243236 A, JP 2013-242366 A, JP 2013-243371 A, JP 2013-245179 A, JP 2014-003249 A, JP 2014-003299 A, JP 2014-013910 A, JP 2014-017493 A, JP 2014-017494 A, and the like.

Next, the details of each layer configuring the organic EL element according to the present invention will be described.

[Transparent Base Material]

Examples of the transparent base material (3) which can be applied to the organic EL element according to the present invention are capable of including a transparent material such as glass and plastic. Examples of the transparent base material (3) which is preferably used, are capable of including glass, quartz, and a resin film.

Examples of the glass material include silica glass, soda lime silica glass, lead glass, borosilicate glass, alkali-free glass, and the like. It is possible to form a film which is formed of an inorganic substance or an organic substance by physical processing such as grinding or a hybrid film in which the film is combined on a front surface of the glass material, as necessary, from the viewpoint of adhesiveness, durability, and smoothness with respect to the adjacent layer.

Examples of the resin material configuring the resin film are capable of including polyester such as polyethylene terephthalate (simply referred to as PET) and polyethylene naphthalate (simply referred to as PEN), cellulose esters such as polyethylene, polypropylene, cellophane, cellulose diacetate, cellulose triacetate (simply referred to as TAC), cellulose acetate butyrate, cellulose acetate propionate (simply referred to as CAP), cellulose acetate phthalate, and cellulose nitrate, and derivatives thereof, a cycloolefin-based resin such as polyvinylidene chloride, polyvinyl alcohol, polyethylene vinyl alcohol, syndiotactic polystyrene, polycarbonate, norbornene resin, polymethyl pentene, polyether keton, polyimide, polyether sulfone (simply referred to as PES), polyphenylene sulfide, polysulfones, polyether imide, polyether keton imide, polyamide, fluorine resin, nylon, polymethyl methacrylate, acryl and polyarylates, ARTON (Product Name manufactured by JSR Corporation), and APEL (Product Name manufactured by Mitsui Chemicals, Inc.), and the like.

In the organic EL element, a gas barrier layer may be disposed on the transparent base material (3) described above, as necessary.

A material forming the gas barrier layer may be a having a function of suppressing the infiltration of a component, such as material moisture or oxygen, which causes performance degradation of the organic EL element, and for example, an inorganic substance such as silicon oxide, silicon dioxide, and silicon nitride can be used. Further, in order to improve the brittleness of the gas barrier layer, it is more preferable to have a laminate structure of an organic layer formed of an inorganic layer and an organic material. A lamination order of the inorganic layer and the organic layer is not particularly limited, and it is preferable that the inorganic layer and the organic layer are laminated on each other a plurality of times.

(Anode Electrode: Positive Electrode)

Examples of the positive electrode configuring the organic EL element are capable of including a metal such as Ag and Au, or an alloy containing a metal as a main component, CuI, or a metal oxide such as a composite oxide of indium-tin (ITO), SnO₂, and ZnO, the metal or the alloy containing the metal as a main component is preferable, and silver or an alloy containing silver as a main component is more preferable.

In a case where the transparent positive electrode is configured by containing silver as a main component, it is preferable that purity of silver is greater than or equal to 99%. In addition, in order to ensure stability of silver, palladium (Pd), copper (Cu), gold (Au), and the like may be added.

The transparent positive electrode is a layer configured by containing silver as a main component, and specifically, may be formed by only using silver, or may be configured of an alloy containing silver (Ag). Examples of such alloy include silver-magnesium (Ag—Mg), silver-copper (Ag—Cu), silver-palladium (Ag—Pd), silver-palladium-copper (Ag—Pd—Cu), silver-indium (Ag—In), and the like.

In each configuration material configuring the positive electrode described above, a transparent positive electrode is preferable in which silver is contained as a main component and a thickness is in a range of 2 nm to 20 nm, and a transparent positive electrode is more preferable in which a thickness is in a range of 4 nm to 12 nm, as the positive electrode configuring the organic EL element according to the present invention. It is preferable the thickness is less than or equal to 20 nm, since an absorptive component and a reflective component of the transparent positive electrode are suppressed to be low, and a high light transmission rate is maintained.

In the layer configured by containing silver as a main component of the present invention, a content of silver in the transparent positive electrode may be greater than or equal to 60 mass %, and the content of silver is preferably greater than or equal to 80 mass %, the content of silver is more preferably greater than or equal to 90 mass %, and the content of silver is particularly preferably greater than or equal to 98 mass %. In addition, “transparent” in the transparent positive electrode according to the present invention indicates that a light transmission rate at a wavelength of 550 nm is greater than or equal to 50%.

In the transparent positive electrode, the layer configured by containing silver as a main component may have a configuration in which a plurality of layers are laminated, as necessary.

In addition, in the present invention, in a case where the positive electrode is the transparent positive electrode configured by containing silver as a main component, it is preferable that an underlayer is disposed on a lower portion thereof from the viewpoint of increasing homogeneousness of a silver film in the transparent positive electrode to be formed. The underlayer is not particularly limited, but a layer containing an organic compound having a nitrogen atom or a sulfur atom is preferable, and a method of forming the transparent positive electrode on the underlayer is a preferred aspect.

[Intermediate Electrode]

The organic EL element according to the present invention has a structure in which two or more organic functional layer units configured of each of an organic functional layer and a light emitting layer are laminated between the positive electrode and the negative electrode, and two or more organic functional layer units can be separated from each other by an intermediate electrode layer unit including an independent connection terminal for obtaining electric connection.

[Light Emitting Layer]

It is preferable that the light emitting layer configuring the organic EL element contains a phosphorescent light emitting compound as a light emitting material.

The light emitting layer is a layer emitting layer according to recoupling between an electron injected from the electrode or the electron transporting layer and a hole injected from the hole transporting layer, and a portion emitting light may be in the light emitting layer, or may be on interface between the light emitting layer and the adjacent layer.

The configuration of such a light emitting layer is not particularly limited insofar as a light emitting material to be contained satisfies a light emitting requirement. In addition, the light emitting layer may be a plurality of layers having the same light emitting spectrum or the same light emission maximum wavelength. In this case, it is preferable that an interlayer having non-light emitting properties is disposed between the respective light emitting layers.

The sum of the thicknesses of the light emitting layers is preferably in a range of approximately 1 nm to 100 nm, and is more preferably in a range of 1 nm to 30 nm, from the viewpoint of emitting light at a lower driving voltage. Furthermore, in a case where the interlayer having non-light emitting properties exists between the light emitting layers, the sum of the thicknesses of the light emitting layers is a thickness also including the interlayer.

In the light emitting layer described above, light emitting material or a host compound described below, for example, can be formed by a known method such as a vacuum vapor deposition method, a spin coating method, a casting method, a Langmuir Blodgett method (an LB method), and an ink jet method.

In addition, in the light emitting layer, a plurality of light emitting materials may be mixed, or a phosphorescent light emitting material and a fluorescent light emitting material (also referred to as a fluorescent dopant and a fluorescent compound) may be mixed in the same light emitting layer. In the configuration of the light emitting layer, it is preferable that a host compound (also referred to as a light emitting host or the like) and a light emitting material (also referred to as a light emitting dopant compound) are contained, and light is emitted from the light emitting material.

<Host Compound>

A compound in which a phosphorescent quantum yield of phosphorescent light emission at a room temperature (25° C.) is less than 0.1, is preferable as the host compound contained in the light emitting layer. It is more preferable that the phosphorescent quantum yield is less than 0.01. In addition, it is preferable that a volume ratio in the light emitting layer is greater than or equal to 50%, in the compound contained in the light emitting layer.

A known host compound may be independently used as the host compound, or a plurality of host compounds may be used. By using a plurality of host compounds, it is possible to control the movement of the charge, and to increase the efficiency of the organic EL element. In addition, by using a plurality of light emitting materials described below, it is possible to mix different light emitting components, and thus, to obtain an arbitrary light emission color.

The host compound used in the light emitting layer may be a known low molecular compound of the related art, may be polymer compound having a repeating unit, or may be a low molecular compound (a vapor deposition polymerizable light emitting host) having a polymerizable group such as a vinyl group or an epoxy group.

Examples of the host compound which can be applied to the present invention are capable of including compounds described in JP 2001-257076 A, JP 2001-357977 A, JP 2002-8860 A, JP 2002-43056 A, JP 2002-105445 A, JP 2002-352957 A, JP 2002-231453 A, JP 2002-234888 A, JP 2002-260861 A, JP 2002-305083 A, US 2005/0112407 A, US 2009/0030202 A, WO 2001/039234 A, WO 2008/056746 A, WO 2005/089025 A, WO 2007/063754 A, WO 2005/030900 A, WO 2009/086028 A, WO 2012/023947 A, JP 2007-254297 A, EP 2034538 A, and the like.

<Light Emitting Material>

Examples of a representative light emitting material which can be used in the present invention include a phosphorescent light emitting compound (also referred to as a phosphorescent compound, a phosphorescent light emitting material, or a phosphorescent light emitting dopant) and a fluorescent light emitting compound (also referred to as a fluorescent compound or a fluorescent light emitting material).

<Phosphorescent Light Emitting Compound>

The phosphorescent light emitting compound is a compound in which light emission from an excited triplet is observed, and specifically, is a compound in which phosphorescent light is emitted at a room temperature (25° C.), is defined as a compound in which a phosphorescent quantum yield is greater than or equal to 0.01 at 25° C., and a preferred phosphorescent quantum yield is greater than or equal to 0.1.

The phosphorescent quantum yield described above can be measured by a method described in Fourth Edition Spectroscopy II of Experimental Chemistry Course 7, page 398 (1992 edition, published by MARUZEN-YUSHODO Company, Limited). The phosphorescent quantum yield in a solution can be measured by using various solvents, but in the present invention, in the case of using the phosphorescent light emitting compound, it is preferable that the phosphorescent quantum yield of greater than or equal to 0.01 is attained in an arbitrary solvent.

The phosphorescent light emitting compound can be used by being suitably selected from known compounds which are used in a light emitting layer of a general organic EL element, is preferably a complex-based compound containing metals of groups 8 to 10 in a periodic table of elements, is more preferably an iridium compound, an osmium compound, a platinum compound (a platinum complex-based compound), or a rare earth complex, and among them, the iridium compound is most preferable.

In the present invention, at least one light emitting layer may contain two types or more phosphorescent light emitting compounds, or may have an aspect in which a concentration ratio of the phosphorescent light emitting compound in the light emitting layer is changed in a thickness direction of the light emitting layer.

A specific example of a known phosphorescent light emitting compound which can be used in the present invention is capable of including compounds or the like described in the following literatures.

Compounds described in Nature 395, 151(1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991 A, WO 2008/101842 A, WO 2003/040257 A, US 2006/835469 A, US 2006/0202194 A, US 2007/0087321 A, US 2005/0244673 A can be included.

In addition, compounds described in Inorg. Chem. 40, 1704 (2001), Chem. Mater. 16, 2480 (2004), Adv. Mater. 16, 2003 (2004), Angew. Chem. lnt. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290 A, WO 2009/000673 A, U.S. Pat. No. 7,332,232, US 2009/0039776 A, U.S. Pat. No. 6,687,266, US 2006/0008670 A, US 2008/0015355 A, U.S. Pat. No. 7,396,598, US 2003/0138657 A, U.S. Pat. No. 7,090,928, and the like can be included.

In addition, compounds described in Angew. Chem. lnt. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2006/056418 A, WO 2005/123873 A, WO 2005/123873 A, WO 2006/082742 A, US 2005/0260441 A, U.S. Pat. No. 7,534,505, US 2007/0190359 A, U.S. Pat. No. 7,338,722, U.S. Pat. No. 7,279,704, US 2006/103874 A, and the like can also be included.

Further, compounds described in WO 2005/076380 A, WO 2008/140115 A, WO 2011/134013 A, WO 2010/086089 A, WO 2012/020327 A, WO 2011/051404 A, WO 2011/073149 A, JP 2009-114086 A, JP 2003-81988 A, JP 2002-363552 A, and the like can also be included.

In the present invention, examples of a preferred phosphorescent light emitting compound include an organic metal complex having Ir in a center metal. A complex having at least one coordination manner of a metal-carbon bond, a metal-nitrogen bond, a metal-oxygen bond, and a metal-sulfur bond is more preferable.

The phosphorescent light emitting compound described above (also referred to as a phosphorescent light emitting metal complex), for example, can be synthesized by using methods disclosed in Organic Letter magazine, vol 3, No. 16, 2579-2581 (2001), Inorganic Chemistry, Vol. 30, No. 8, 1685-1687 (1991), J. Am. Chem. Soc. Vol. 123, page 4304 (2001), Inorganic Chemistry, Vol. 40, No. 7, pp. 1704-1711 (2001), Inorganic Chemistry, Vol. 41, No. 12, pp. 3055-3066 (2002), New Journal of Chemistry., Vol. 26, page 1171 (2002), and European Journal of Organic Chemistry, Volume 4, 695-709 (2004), reference literatures described in such literatures, and the like.

<Fluorescent Light Emitting Compound>

Examples of the fluorescent light emitting compound include a coumarin-based pigment, a pyran-based pigment, a cyanine-based pigment, a croconium-based pigment, a squalium-based pigment, an oxobenzanthracene-based pigment, a fluorescein-based pigment, a rhodamine-based pigment, a pyrylium-based pigment, a perylene-based pigment, a stilbene-based pigment, a polythiophene-based pigment, a rare earth complex-based fluorescent body, or the like.

[Organic Functional Layer Unit]

Next, the charge injecting layer, the hole transporting layer, the electron transporting layer, and an inhibiting layer will be described in this order, as each layer configuring the organic functional layer unit, other than the light emitting layer.

(Charge Injecting Layer)

The charge injecting layer is a layer disposed between the electrode and the light emitting layer in order to decrease a driving voltage or to improve a light emission brightness, and the details thereof are described in Chapter 2 “Electrode Materials” (pages 123 to 166) of Chapter 2 of “Organic EL Element and its Industrialization Front Line (Nov. 30, 1998, published by NTS Inc.)”, and there are the hole injecting layer and the electron injecting layer.

In general, it is possible to allow the hole injecting layer to exist between the positive electrode and the light emitting layer or the hole transporting layer, and the electron injecting layer to exist between the negative electrode and the light emitting layer or the electron transporting layer, but in the present invention, it is preferable that the charge injecting layer is disposed to be adjacent to the transparent electrode.

The hole injecting layer is a layer disposed to be adjacent to the positive electrode, which is the transparent electrode, in order to decrease a driving voltage or to improve a light emission brightness, and the details thereof are described in Chapter 2 “Electrode Materials” (pages 123 to 166) of Chapter 2 of “Organic EL Element and its Industrialization Front Line (Nov. 30, 1998, published by NTS Inc.)”.

The details of the hole injecting layer are also described in JP 9-45479 A, JP 9-260062 A, and JP 8-288069 A, and examples of a material used in the hole injecting layer include a porphyrin derivative, a phthalocyanine derivative, an oxazole derivative, an oxadiazole derivative, a triazole derivative, an imidazole derivative, a pyrazoline derivative, a pyrazolone derivative, a phenylene diamine derivative, a hydrazone derivative, a stilbene derivative, a polyaryl alkane derivative, a triaryl amine derivative, a carbazole derivative, an indolocarbazole derivative, an isoindole derivative, an acene-based derivative such as anthracene or naphthalene, a fluorene derivative, a fluorenone derivative, a polymer material or an oligomer in which polyvinyl carbazole or aromatic amine is introduced into a main chain or a side chain, polysilane, a conductive polymer or oligomer (for example, polyethylene dioxythiophene (PEDOT): a polystyrene sulfonic acid (PSS), an aniline-based copolymer, polyaniline, polythiophene, and the like), and the like.

Examples of the triaryl amine derivative include a benzidine type compound represented by 4,4′-bis[N-(1-naphthyl)-N-phenyl amino] biphenyl (α-NPD), a starburst type compound represented by 4,4′,4″-tris[N-(3-methyl phenyl)-N-phenyl amino] triphenyl amine (MTDATA), a compound having fluorene or anthracene in a triaryl amine coupling core portion, and the like.

In addition, a hexaazatriphenylene derivative as described in JP 2003-519432 A, JP 2006-135145 A, or the like can also be used as a hole transporting material.

The electron injecting layer is a layer disposed between the negative electrode and the light emitting layer in order to decrease a driving voltage or to improve a light emission brightness, and in a case where the negative electrode is configured of the transparent electrode according to the present invention, the electron injecting layer is disposed to be adjacent to the transparent electrode, and the details thereof are described in Chapter 2 “Electrode Materials” (pages 123 to 166) of Chapter 2 of “Organic EL Element and its Industrialization Front Line (Nov. 30, 1998, published by NTS Inc.)”.

The details of the electron injecting layer are also described in JP 6-325871 A, JP 9-17574 A, JP 10-74586 A, and the like, and a specific example of a material preferably used in the electron injecting layer includes a metal represented by strontium, aluminum, or the like, an alkali metal compound represented by lithium fluoride, sodium fluoride, potassium fluoride, or the like, an alkali metal halide layer represented by magnesium fluoride, calcium fluoride, or the like, an alkali earth metal compound layer represented by magnesium fluoride, a metal oxide represented by molybdenum oxide, aluminum oxide, or the like, a metal complex represented by lithium 8-hydroxy quinolate (Liq) or the like, and the like. In addition, in a case where the negative electrode is the transparent electrode, an organic material such as a metal complex is particularly preferably used. It is desirable that the electron injecting layer is an extremely thin film, a layer thickness thereof depends on a configuration material, and it is preferable that the layer thickness is in a range of 1 nm to 10 μm.

(Hole Transporting Layer)

The hole transporting layer is formed of a hole transporting material having a function of transporting a hole, and in a broad sense, the hole injecting layer and the electron inhibiting layer also have the function of the hole transporting layer. The hole transporting layer can be disposed as a single layer or a plurality of layers.

The hole transporting material has any one of injecting or transporting of the hole and barrier properties of the electron, and may be any one of an organic substance and an inorganic substance. Examples of the hole transporting material include a triazole derivative, an oxadiazole derivative, an imidazole derivative, a polyaryl alkane derivative, a pyrazoline derivative, a pyrazolone derivative, a phenylene diamine derivative, an aryl amine derivative, an amino-substituted chalcone derivative, an oxazole derivative, a styryl anthracene derivative, a fluorenone derivative, a hydrazone derivative, a stilbene derivative, a silazane derivative, an aniline-based copolymer, a conductive polymer oligomer, a thiophene oligomer, and the like.

The materials described above can be used as the hole transporting material, a porphyrin compound, an aromatic tertiary amine compound, and a styryl amine compound can be used, and it is particularly preferable to use the aromatic tertiary amine compound.

A representative example of the aromatic tertiary amine compound and the styryl amine compound includes N,N,N′,N′-tetraphenyl-4,4′-diaminophenyl, N,N′-diphenyl-N,N′-bis(3-methyl phenyl)-[1,1′-biphenyl]-4,4′-diamine (simply referred to as TPD), 2,2-bis(4-di-p-tolyl aminophenyl) propane, 1,1-bis(4-di-p-tolyl aminophenyl) cyclohexane, N,N,N′,N′-tetra-p-tolyl-4,4′-diaminobiphenyl, 1,1-bis(4-di-p-tolyl aminophenyl)-4-phenyl cyclohexane, bis(4-dimethyl amino-2-methyl phenyl) phenyl methane, bis(4-di-p-tolyl aminophenyl) phenyl methane, N,N′-diphenyl-N,N′-di(4-methoxy phenyl)-4,4′-diaminobiphenyl, N,N,N′,N′-tetraphenyl-4,4′-diaminodiphenyl ether, 4,4′-bis(diphenyl amino) quadriphenyl, N,N,N-trip-tolyl) amine, 4-(di-p-tolyl amino)-4′-[4-(di-p-tolyl amino) styryl] stilbene, 4-N,N-diphenyl amino-(2-diphenyl vinyl) benzene, 3-methoxy-4′-N,N-diphenyl aminostilbenzene, N-phenyl carbazole, and the like.

The hole transporting layer can be formed by thinning the hole transporting material described above, for example, according to a known method such as a vacuum vapor deposition method, a spin coating method, a casting method, a printing method including an ink jet method, and a Langmuir Blodgett method (an LB method). A layer thickness of the hole transporting layer is not particularly limited, and in general, is approximately in a range of 5 nm to 5 μm, and is preferably in a range of 5 nm to 200 nm. The hole transporting layer may have a one-layer structure formed of one type or two or more types of the materials described above.

In addition, the material of the hole transporting layer is doped with impurities, and thus, it is possible to improve p properties. Examples of the material include materials described in JP 4-297076 A, JP 2000-196140 A, JP 2001-102175 A, J. Appl. Phys., 95, 5773 (2004), and the like.

Thus, it is preferable to increase the p properties of the hole transporting layer, since it is possible to prepare an organic EL element having lower power consumption.

(Electron Transporting Layer)

The electron transporting layer is configured of a material having a function of transporting an electron, and in a broad sense, the electron injecting layer or a hole inhibiting layer are also included in the electron transporting layer. The electron transporting layer can be disposed as a single layer structure or a laminate structure of a plurality of layers.

In the electron transporting layer of a single layer structure and the electron transporting layer of a laminate structure, it is preferable that an electron transporting material configuring a layer portion adjacent to the light emitting layer (also functions as a hole inhibiting material) has a function of transporting an electron injected by the cathode (the negative electrode) to the light emitting layer. An arbitrary material can be used by being selected from known compounds of the related art, as the material described above. Examples of the material described above include a nitro-substituted fluorene derivative, a diphenyl quinone derivative, a thiopyran dioxide derivative, carbodiimide, a fluorenylidene methane derivative, anthraquinodimethane, an anthrone derivative, an oxadiazole derivative, and the like. Further, in the oxadiazole derivatives described above, a thiadiazole derivative in which an oxygen atom of an oxadiazole ring is substituted with a sulfur atom, and a quinoxaline derivative which has a quinoxaline ring known as an electron withdrawing group can also be used as the material of the electron transporting layer. Further, a polymer material in which such materials are introduced into a polymer chain or a polymer material in which such materials are contained as a main chain of the polymer can be used.

In addition, a metal complex of a 8-quinolinol derivative, for example, tris(8-quinolinol) aluminum (simply referred to as Alq3), tris(5,7-dichloro-8-quinolinol) aluminum, tris(5,7-dibromo-8-quinolinol) aluminum, tris(2-methyl-8-quinolinol) aluminum, tris(5-methyl-8-quinolinol) aluminum, bis(8-quinolinol) zinc (simply referred to as Znq), and the like, and a metal complex in which a center metal of the metal complex is substituted with In, Mg, Cu, Ca, Sn, Ga, or Pb, can also be used as the material of the electron transporting layer.

The electron transporting layer can be formed by thinning the material described above, for example, according to a known method such as a vacuum vapor deposition method, a spin coating method, casting method, a printing method including an ink jet method, and an LB method. A layer thickness of the electron transporting layer is not particularly limited, and in general, is approximately in a range of 5 nm to 5 μm, and is preferably in a range of 5 nm to 200 nm. The electron transporting layer may have a single structure of one type or two or more types of the materials described above.

(Inhibiting Layer)

Examples of the inhibiting layer include a hole inhibiting layer and an electron inhibiting layer, and is a layer which is disposed as necessary, in addition to each configuration layer of the organic functional layer unit 5 described above. Examples of the inhibiting layer are capable of including a hole inhibiting (hole blocking) layer and the like described in JP 11-204258 A, JP 11-204359 A, page 237 of “Organic EL Element and its Industrialization Front Line (Nov. 30, 1998, published by NTS Inc.)”, and the like.

The hole inhibiting layer, in a broad sense, has the function of the electron transporting layer. The hole inhibiting layer is formed of a hole inhibiting material having a function of rarely transporting a hole while having a function of transporting an electron, and inhibits the hole while transporting the electron, and thus, it is possible to improve recoupling probability between the electron and the hole. In addition, the configuration of the electron transporting layer can be used as the hole inhibiting layer, as necessary. It is preferable that the hole inhibiting layer is disposed to be adjacent to the light emitting layer.

On the other hand, the electron inhibiting layer, in a broad sense, has the function of the hole transporting layer. The electron inhibiting layer is formed of a material having a function of rarely transporting an electron while having a function of transporting a hole, and inhibits the electron while transporting the hole, and thus, it is possible to improve the recoupling probability between the electronic and the hole. In addition, the configuration of the hole transporting layer can be used as the electron inhibiting layer, as necessary. A layer thickness of the hole inhibiting layer which is applied to the present invention is preferably in a range of 3 nm to 100 nm, and is more preferably in a range of 5 nm to 30 nm.

[Negative Electrode]

The negative electrode is an electrode layer which functions for supplying a hole to the organic functional layer unit or the light emitting layer, and a metal, an alloy, an organic or inorganic conductive compound, or a mixture thereof is used in the negative electrode. Specifically, examples of the material include gold, aluminum, silver, magnesium, lithium, a magnesium/copper mixture, a magnesium/silver mixture, a magnesium/aluminum mixture, a magnesium/indium mixture, indium, a lithium/aluminum mixture, a rare earth metal, an oxide semiconductor such as ITO, ZnO, TiO₂, and SnO₂, and the like.

The negative electrode can be prepared by thinning such a conductivity material according to a method of vapor deposition, sputtering, or the like. In addition, sheet resistance of a second electrode is preferably less than or equal to hundreds Q/sq., and a film thickness is generally selected from a range of 5 nm to 5 μm, and is preferably selected from a range of 5 nm to 200 nm.

Furthermore, in a case where the organic EL element is a double-sided light emitting element in which emission light L is emitted even from the negative electrode, the organic EL element may be configured by selecting a negative electrode having excellent light transmissive properties.

[Sealing Member]

As illustrated in FIG. 2, examples of a sealing method used for sealing the organic EL element are capable of including a method of allowing the sealing member (8), the negative electrode (6), and the transparent substrate (3) to adhere to each other through the adhesive agent (7) for sealing.

The sealing member (8) may be disposed to cover a display region of the organic EL element, and may be in the shape of a concave plate, or may be in the state of a flat plate. In addition, transparency and electric insulating properties are not particularly limited.

Specifically, examples of the sealing member include a glass plate, a polymer plate, a film, a metal plate, a film, and the like. In particular, examples of the glass plate are capable of including soda lime glass, barium and strontium-containing glass, lead glass, aluminosilicate glass, borosilicate glass, barium borosilicate glass, quartz, and the like. In addition, examples of the polymer plate are capable of including polycarbonate, acryl, polyethylene terephthalate, polyether sulfide, polysulfone, and the like. Examples of the metal plate include one type or more metals or alloys selected from the group consisting of stainless steel, iron, copper, aluminum, magnesium, nickel, zinc, chromium, titanium, molybdenum, silicon, germanium, and tantalum.

A polymer film and a metal film can be preferably used as the sealing member (8), from the viewpoint of thinning the organic EL element. Further, in the polymer film, it is preferable that a water vapor permeability at a temperature is 25±0.5° C. and relative humidity of 90±2% RH, which is measured by a method based on JIS K 7129-1992, is less than or equal to 1×10⁻³ g/m²·24 h, and it is more preferable that an oxygen permeability measured by a method based on JIS K 7126-1987 is less than or equal to 1×10⁻³ ml/m²·24 h·atm (1 atm is 1.01325×10⁵ Pa), and the water vapor permeability at a temperature of 25±0.5° C. and relative humidity of 90±2% RH is less than or equal to 1×10⁻³ g/m²·24 h.

Examples of the adhesive agent (7) for sealing are capable of including photocurable and thermal curable adhesive agent having a reactive vinyl group of an acrylic acid-based oligomer and a methacrylic acid-based oligomer, a moisture curable adhesive agent such as 2-cyanoacrylic acid ester, and the like. In addition, a thermal and chemical curable (two-liquid mixed) adhesive agent such as epoxy can be included. In addition, hot-melt type polyamide, polyester, and polyolefin can be included. In addition, a cationic curable and ultraviolet curable epoxy resin adhesive agent can be included.

In a gas phase and a liquid phase, Inert gas such as nitrogen and argon, or fluorohydrocarbon, an inert liquid such as silicon oil can also be injected into a gap between the sealing member and the display region (the light emitting region) of the organic EL element, in addition to the adhesive agent (7) for sealing. In addition, it is also possible to set the gap between the sealing member and the display region of the organic EL element to be in vacuum, or to seal the gap with a hygroscopic compound.

[Manufacturing Method of Organic EL Element]

In a manufacturing method of the organic EL element, the organic EL element can be formed by laminating the positive electrode, the organic functional layer unit including the light emitting layer, and the negative electrode on a transparent base material.

First, the transparent base material is prepared, and a thin film formed of a desired electrode substance, for example, a substance for a positive electrode, is formed on the transparent base material by a method of vapor deposition, sputtering, or the like such that a film thickness is less than or equal to 1 μm, and is preferably in range of 10 nm to 200 nm, and thus, the positive electrode is formed. Simultaneously, a connection electrode portion to be connected an external power source is formed in a positive electrode end portion.

Next, the hole injecting layer, the hole transporting layer, the light emitting layer, the electron transporting layer, and the like are laminated thereon in this order, as the organic functional layer unit.

In the formation of each of the organic functional layers, a spin coating method, a casting method, an ink jet method, a vapor deposition method, a printing method, and the like are used, and the vacuum vapor deposition method or the spin coating method is particularly preferable from the viewpoint of easily obtaining a homogeneous layer and of rarely forming a pinhole. Further, a different forming method may be applied to each layer. In a case where the vapor deposition method is adopted in the formation of each of the layers, a vapor deposition condition is different according to the type of compound to be used, or the like, and in general, a boat heating temperature is 50° C. to 450° C., a vacuum degree is 1×10⁻⁶ Pa to 1×10⁻² Pa, a vapor deposition rate is 0.01 nm/second to 50 nm/second, a substrate temperature is −50° C. to 300° C., a layer thickness is in a range of 0.1 μm to 5 μm, and it is desirable that each condition is suitably selected.

As described above, the organic functional layer unit is formed, and then, the negative electrode is formed on the upper portion thereof by a suitable forming method such as a vapor deposition method or a sputtering method. At this time, the negative electrode has a pattern in the shape where a terminal portion is drawn out from the upper portion of the organic functional layer unit to the circumference of the transparent substrate while an insulating state with respect to the positive electrode is maintained by the organic functional layer unit.

The negative electrode is formed, and then, the transparent base material, the positive electrode, the organic functional layer unit including the light emitting layer, and the negative electrode are sealed with the sealing material. That is, in a state where terminal portions of the positive electrode and the negative electrode are exposed, the sealing material covering at least the organic functional layer unit is provided on the transparent base material.

In addition, In the manufacturing of the organic EL panel, for example, each of the electrodes of the organic EL element, the light emitting element driving circuit unit (12), or the hovering detection circuit unit (14) are electrically connected to each other, but an electric connection member which can be used at this time, is not particularly limited insofar as the electric connection member is a member having conductivity, and an anisotropic conductive film (ACF), a conductive paste, or a metal paste is a preferred aspect.

Examples of the anisotropic conductive film (ACF) are capable of including a layer containing fine conductive particles having conductivity mixed with a thermal curable resin. A conductive particle-containing layer which can be used in the present invention is not particularly limited insofar as a layer contains conductive particles as an anisotropic conductive member, but can be suitably selected according to the object. Conductive particles which can be used as the anisotropic conductive member according to the present invention is not particularly limited, but can be suitably selected according to the object, and examples of the conductive particles include metal particles, resin particles covered with a metal, and the like. Examples of commercially available ACF are capable of including a low temperature curable ACF which can also be applied to a resin film, such as MF-331 (manufactured by Hitachi Chemical Company, Ltd.).

Examples of the metal particles include nickel, cobalt, silver, copper, gold, palladium, and the like, examples of the resin particles covered with a metal include particles of which a front surface of a resin core is covered with any one metal of nickel, copper, gold, and palladium, and examples of the metal paste are capable of including a commercially available metal nanoparticle paste, or the like.

<<Application Field of Organic EL Module>>

The organic electroluminescence module of the present invention is an organic electroluminescence module which is capable of being small formatted and miniaturized, and of simplifying a process, and can be suitably used in various smart devices such as a smart phone or a tablet, and an illuminating device.

[Smart Device]

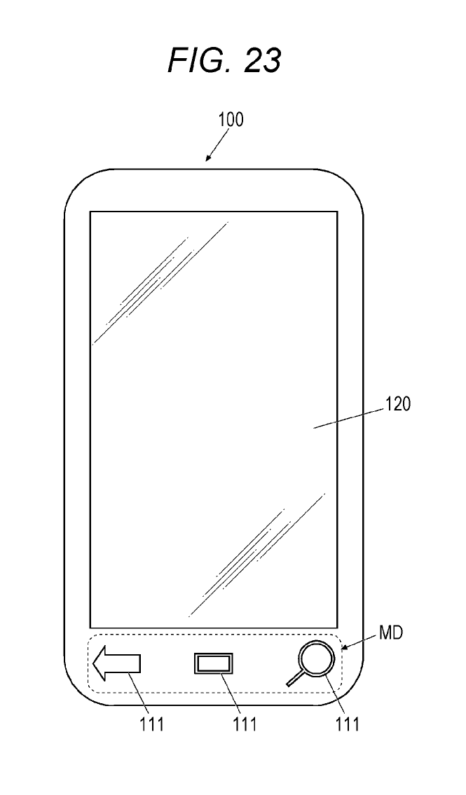

FIG. 23 is a schematic configuration diagram illustrating an example of a smart device (100) including the organic EL module of the present invention in an icon portion. The organic EL module of the present invention can be applied to a main screen or the like in addition to the icon portion.

The smart device (100) of the present invention includes an organic electroluminescence module (MD) having the hovering detection function illustrated in FIG. 2 to FIG. 22, a liquid crystal display device (120), and the like. A known liquid crystal display device of the related art can be used as the liquid crystal display device (120).

FIG. 23 illustrates a state where the organic electroluminescence module (MD) of the present invention emits light, and light emission of various display patterns (111) seen from a front side is viewed. In a case where the organic electroluminescence module (MD) is in a non-light emission state, various display patterns (111) are not viewed. Furthermore, the shape of the display pattern (111) illustrated in FIG. 23 is merely an example, and not particularly limited, and may be any diagram, character, aspect, or the like. Here, the “display pattern” indicates design (a pattern and an aspect of a drawing), a character, an image, or the like displayed by light emission of the organic EL element.

[Illuminating Device]

The organic electroluminescence module of the present invention can also be applied to an illuminating device. The illuminating device including the organic electroluminescence module of the present invention is also useful to a display device such as a household lighting, an interior lighting, a backlight of a liquid crystal display device. In addition, a wide range of application is included, such as a backlight of a watch or the like, a light source of signboard advertisement, a traffic light, an optical storage medium, or the like, a light source of an electrophotographic copier, a light source of an optical communication processor, a light source or an optical sensor, and the like, and a general household electric appliance which requires a display device.

### INDUSTRIAL APPLICABILITY

The organic electroluminescence module of the present invention is an organic electroluminescence module which is capable of being small formatted and miniaturized, and of simplifying a process, and can be suitably used for various smart devices such as a smart phone or a tablet, and an illuminating device.

### REFERENCE SIGNS LIST

1, MD organic EL module
2 organic EL panel
3 transparent base material
4 anode electrode
4A anode electrode functioning as hovering detection electrode
5 organic functional layer unit
6 cathode electrode
6A cathode electrode functioning as hovering detection electrode
7 adhesive agent for sealing
8 sealing member
9 hovering detection unit
10 touch detection electrode of related art
11 cover glass
12 light emitting element driving circuit unit
13 separated touch detection circuit unit
14 hovering detection circuit unit
15 finger
16 earth
21 capacitor (Cel)
22 organic EL element
23 light emitting element driving circuit portion
24 hovering detection circuit portion
25 anode electrode wiring
26 cathode electrode wiring
27, 27A, 27B ground
28 light emitting control information route
29 hovering detection information route
30 capacitor (Cs)
100 smart device
111 display pattern
120 liquid crystal display device
1FT one frame period
Cf electrostatic capacitance at time of finger touch
LT light emitting period
ST sensing period
SW1 switch 1
SW2 switch 2
SW3 switch 3
SW4 switch 4
t standby time
τ constant at time of charging and discharging OLED

1. An organic electroluminescence module having a hovering detection function, the module comprising:
a hovering detection circuit unit including an electrostatic capacitance type hovering detection circuit portion; and
a light emitting element driving circuit unit including a light emitting element driving circuit portion which drives an organic electroluminescence panel,
wherein the organic electroluminescence panel includes a pair of planar electrodes opposing internally,
the pair of electrodes is connected to the light emitting element driving circuit unit, and
any one of the pair of electrodes is a hovering detection electrode, and the hovering detection electrode is connected to the hovering detection circuit unit.

2. The organic electroluminescence module according to claim 1,
wherein the hovering detection circuit unit and the light emitting element driving circuit unit are connected to one common ground.

3. The organic electroluminescence module according to claim 1,
wherein the hovering detection circuit unit and the light emitting element driving circuit unit are each independently connected to a ground.

4. The organic electroluminescence module according to claim 1,
wherein a light emitting period of the organic electroluminescence panel which is controlled by the light emitting element driving circuit portion and a hovering sensing period which is controlled by the hovering detection circuit portion are in a state of being separated from each other.

5. The organic electroluminescence module according to claim 4,
wherein electric capacitance of the organic electroluminescence panel is in a state of not being detected during the hovering sensing period.

6. The organic electroluminescence module according to claim 1,
wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential such that the electric capacitance of the organic electroluminescence panel is not detected during the hovering sensing period.

7. The organic electroluminescence module according to claim 1,
wherein the light emitting period of the organic electroluminescence panel which is controlled by the light emitting element driving circuit portion and the hovering sensing period which is controlled by the hovering detection circuit portion are separated from each other, and the pair of electrodes is in a state of the same potential such that the electric capacitance of the organic electroluminescence panel is not detected during the hovering sensing period.

8. The organic electroluminescence module according to claim 1,
wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential, and the pair of electrodes is in a state of the same potential, such that the electric capacitance of the organic electroluminescence panel is not detected during the hovering sensing period.

9. The organic electroluminescence module according to claim 1,
wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential, and the pair of electrodes is in a state of being short-circuited, such that the electric capacitance of the organic electroluminescence panel is not detected during the hovering sensing period.

10. The organic electroluminescence module according to claim 1,
wherein the organic electroluminescence module is in a driving system in which the organic electroluminescence panel which is controlled by the light emitting element driving circuit portion continuously emits light, and the hovering sensing period which is controlled by the hovering detection circuit portion periodically appears.

11. The organic electroluminescence module according to claim 1,
wherein a reverse applied voltage period is provided at the end of the light emitting period.

12. The organic electroluminescence module according to claim 1, further comprising:
a capacitor between wirings connecting the grounds of the light emitting element driving circuit portion and the hovering detection circuit portion together.

13. A smart device, comprising:
the organic electroluminescence module according to claim 1.

14. An illuminating device, comprising:
the organic electroluminescence module according to claim 1.

15. The organic electroluminescence module according to claim 2,
wherein a light emitting period of the organic electroluminescence panel which is controlled by the light emitting element driving circuit portion and a hovering sensing period which is controlled by the hovering detection circuit portion are in a state of being separated from each other.

16. The organic electroluminescence module according to claim 2,
wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential such that the electric capacitance of the organic electroluminescence panel is not detected during the hovering sensing period.

17. The organic electroluminescence module according to claim 2,
wherein the light emitting period of the organic electroluminescence panel which is controlled by the light emitting element driving circuit portion and the hovering sensing period which is controlled by the hovering detection circuit portion are separated from each other, and the pair of electrodes is in a state of the same potential such that the electric capacitance of the organic electroluminescence panel is not detected during the hovering sensing period.

18. The organic electroluminescence module according to claim 2,
wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential, and the pair of electrodes is in a state of the same potential, such that the electric capacitance of the organic electroluminescence panel is not detected during the hovering sensing period.

19. The organic electroluminescence module according to claim 2,
wherein the light emitting period of the organic electroluminescence panel which is controlled by the light emitting element driving circuit portion and the hovering sensing period which is controlled by the hovering detection circuit portion are separated from each other, and at least one electrode of the pair of electrodes is in a state of a floating potential, and the pair of electrodes is in a state of being short-circuited, such that the electric capacitance of the organic electroluminescence panel is not detected during the hovering sensing period.

20. The organic electroluminescence module according to claim 2,
wherein the organic electroluminescence module is in a driving system in which the organic electroluminescence panel which is controlled by the light emitting element driving circuit portion continuously emits light, and the hovering sensing period which is controlled by the hovering detection circuit portion periodically appears.
